(19) United States
(12) Patent Application Publication
(10) Pub. No.: US 2026/0033111 A1
(43) Pub. Date: Jan. 29, 2026

(54) DISPLAY APPARATUS

(71) Applicant: LG Display Co., Ltd., Seoul (KR)

(72) Inventors: Seunghyeon JU, Jeonju-si (KR); Jaebin SONG, Seoul (KR)

(73) Assignee: LG Display Co., Ltd., Seoul (KR)

(21) Appl. No.: 19/271,116

(22) Filed: Jul. 16, 2025

(30) Foreign Application Priority Data
Jul. 24, 2024 (KR) 10-2024-0098209

(51) Int. Cl. H10H 29/855; H01L 25/16; H10H 29/37; H10H 29/49

(52) U.S. Cl. CPC H10H 29/855; H01L 25/167; H10H 29/37; H10H 29/49; H10H 29/8552

(57) ABSTRACT

A display apparatus in some examples includes a substrate having a plurality of pixels, a plurality of pixel driving circuits disposed on the substrate, a plurality of light-emitting elements disposed on the pixel driving circuit, a contact electrode disposed between the plurality of light-emitting elements and the pixel driving circuit, a first optical layer surrounding the plurality of light-emitting elements, a second optical layer disposed outside the first optical layer, a contact hole disposed in the second optical layer, and an electrode electrically connected to the contact electrode and each of the plurality of light-emitting elements through the contact hole.

### CROSS-REFERENCE TO RELATED APPLICATION

This application claims priority to Korean Patent Application No. 10-2024-0098209, filed on Jul. 24, 2024 in the Korean Intellectual Property Office, the contents of which in its entirety are herein expressly incorporated by reference into the present application.

### BACKGROUND

### Field of the Invention

The present specification relates to a display apparatus.

### Description of the Related Art

Display devices are applied to various electronic devices such as TVs, mobile phones, notebooks, tablets, etc.

Examples of a display device include an organic light-emitting diode (OLED) display apparatus that emits light by itself, a liquid crystal display (LCD) apparatus that requires a separate light source, etc.

Recently, display apparatuses including a light-emitting diode (LED) have been attracting attention as the next-generation display apparatuses. Since a light-emitting element is formed of an inorganic material rather than an organic material, the display apparatus including the LED has a faster lighting speed, better luminous efficiency, and higher luminance images than an LCD or OLED apparatus.

### SUMMARY OF THE DISCLOSURE

Embodiments of the present disclosure are directed to providing a display apparatus in which a contact hole having an electrode electrically connecting a pixel driving circuit to a light-emitting element disposed therein has a fine line width and in which a pattern defect can be prevented or minimized.

In addition, embodiments of the present disclosure are directed to providing a display apparatus in which it is possible to increase extraction efficiency of light emitted from a plurality of light-emitting elements.

In addition, embodiments of the present disclosure are directed to providing a display apparatus in which it is possible to prevent (or minimize) color mixing from occurring between light-emitting elements by arranging an optical layer between the light-emitting elements, thereby increasing light extraction efficiency.

Objects according to embodiments of the present disclosure are not limited to the above-described objects, and other objects and advantages of the present disclosure that are not mentioned can be understood by the following description and will be more clearly understood by the embodiments of the present disclosure. In addition, it will be able to be easily seen that the objects and advantages of the present disclosure can be achieved by devices and combinations thereof that are described in the claims.

According to embodiments of the present disclosure, there is provided a display apparatus including a substrate including a plurality of pixels, a plurality of pixel driving circuits disposed on the substrate, a plurality of light-emitting elements disposed on the pixel driving circuit, a contact electrode disposed between the plurality of light-emitting elements and the pixel driving circuit and configured to electrically connected to the pixel driving circuit, a first optical layer surrounding the plurality of light-emitting elements, a second optical layer disposed outside the first optical layer, a contact hole disposed in the second optical layer, and an electrode disposed on the plurality of light-emitting elements and electrically connected to each of the plurality of light-emitting elements and to the contact electrode through the contact hole.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is an exploded perspective view of a display apparatus according to one or more embodiments of the present disclosure.

FIG. 2 is a plan view of the display apparatus according to the embodiments of the present disclosure.

FIG. 3 is an enlarged view of the display apparatus according to the embodiments of the present disclosure.

FIG. 4 is a view illustrating a circuit structure according to one or more embodiments of the present disclosure.

FIG. 5 is a plan view of the display apparatus according to the embodiments of the present disclosure.

FIG. 6 is a plan view of the display apparatus according to the embodiments of the present disclosure.

FIG. 7 is a plan view of the display apparatus according to the embodiments of the present disclosure.

FIG. 8 is a cross-sectional view of the display device according to one embodiment of the present disclosure.

FIG. 9 is a cross-sectional view of the display device according to one embodiment of the present disclosure.

FIGS. 10 to 13 are views illustrating an apparatus to which the display apparatus according to the embodiments of the present disclosure is applied.

FIG. 14 is a plan view illustrating an area in which one of a plurality of pixel driving circuits is disposed.

FIGS. 15 and 16 are plan views of the display apparatus according to one embodiment of the present disclosure.

FIG. 17 is a cross-sectional view along line I-I′ in FIG. 16.

FIG. 18 is a plan view of the display apparatus according to another embodiment of the present disclosure.

FIG. 19 is a cross-sectional view along line I-I′ in FIG. 18.

FIG. 20 is a cross-sectional view along line II-II′ in FIG. 18.

FIG. 21 is a plan view of a display apparatus according to still another embodiment of the present disclosure.

FIG. 22 is a plan view of a display apparatus according to yet another embodiment of the present disclosure.

FIG. 23 is a cross-sectional view along line I-II′ in FIG. 22.

### DETAILED DESCRIPTION OF THE EMBODIMENTS

Advantages and features of the present disclosure and methods for achieving them will become clear by referencing embodiments described below in detail in conjunction with the accompanying drawings. However, the present disclosure is not limited to the embodiments disclosed below but will be implemented in various different forms, and these embodiments are merely provided to make the disclosure of the present disclosure complete and fully inform those skilled in the art to which the present disclosure pertains of the scope of the present disclosure.

Since shapes, sizes, ratios, angles, numbers, etc. disclosed in the drawings for describing the embodiments of the present disclosure are illustrative, the present disclosure is not limited to the illustrated items. The same reference number denotes the same components throughout the disclosure. In addition, in describing the present disclosure, when it is determined that the detailed description of a related known technology can unnecessarily obscure the gist of the present disclosure, the detailed description thereof will be omitted. When “comprises,” “has,” “consists of,” and the like described in the present disclosure are used, other parts can be added unless “only” is used. When a component is expressed in a singular form, it includes a case in which the component is provided as a plurality of components unless specifically stated otherwise.

In construing a component, the component is construed as including a margin of error even when there is no separate explicit description.

When a positional relationship is described, for example, when the positional relationship between two parts is described using “on,” “above,” “under,” “next to,” etc., one or more other parts can be positioned between the two parts unless “immediately” or “directly” is used.

When a temporal relationship is described, for example, when the temporal relationship is described using “after,” “subsequently,” “then,” “before,” etc., it can include a non-consecutive case unless the term “immediately” or “directly” is used.

Although terms such as first and second are used to describe various components, these components are not limited by these terms. The terms are only used to distinguish one component from another.

Accordingly, a first component described below can be a second component within the technical spirit of the present disclosure.

Features of various embodiments of the present disclosure can be coupled or combined partially or entirely, various technological interworking and driving are made possible, and the embodiments can be implemented independently of each other or implemented together in an associated relationship. Further, the term “can” fully encompasses all the meanings and coverages of the term “may” and vice versa.

Hereinafter, a display apparatus according to various embodiments of the present disclosure will be described with reference to the accompanying drawings. All the components of each display apparatus according to all embodiments of the present disclosure are operatively coupled and configured.

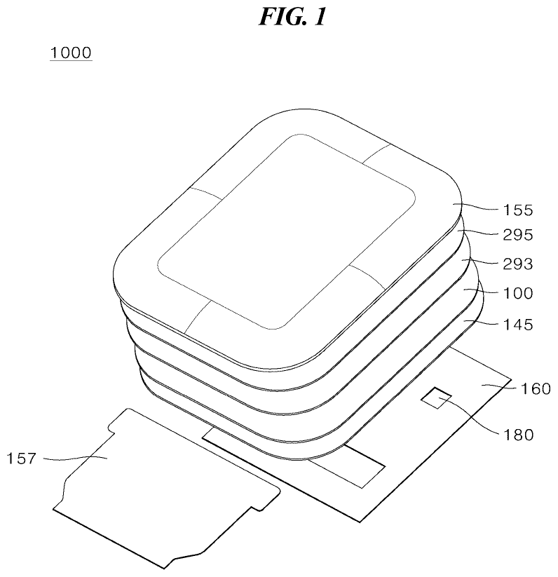

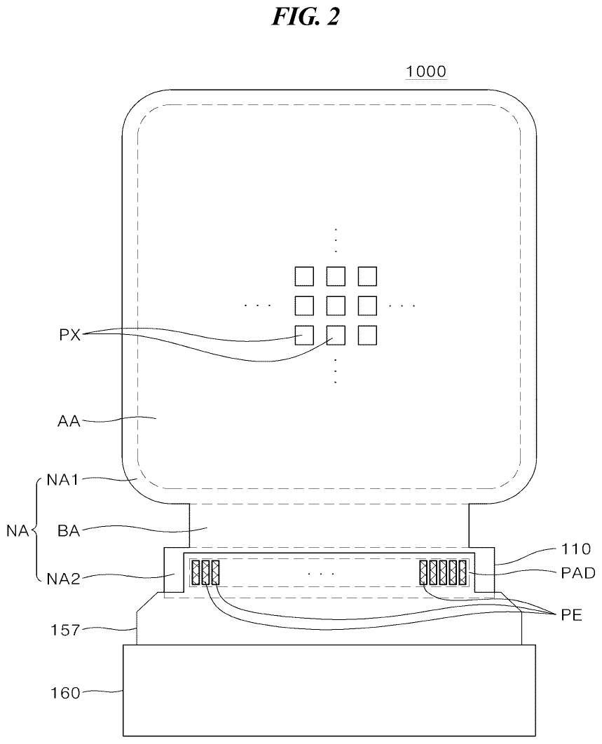

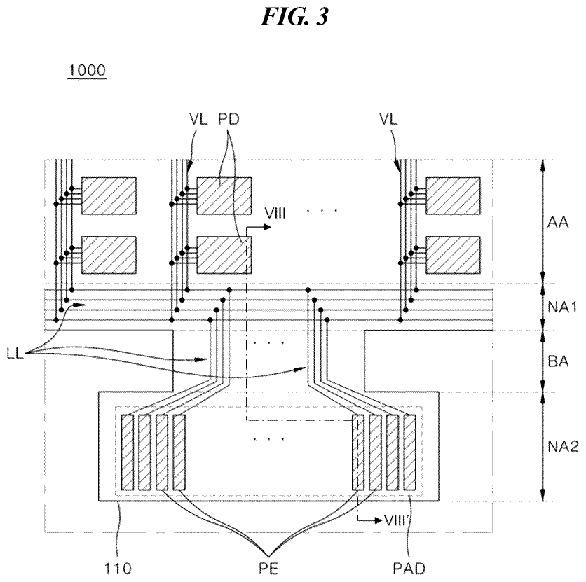

FIG. 1 is an exploded perspective view of a display apparatus according to one or more embodiments of the present disclosure. FIG. 2 is a plan view of the display apparatus according to the embodiments of the present disclosure. FIG. 3 is an enlarged view of the display apparatus according to the embodiments of the present disclosure.

Referring to FIGS. 1 to 3, a display apparatus 1000 according to the embodiments of the present disclosure can include a display panel 100, a polarizing layer 293, an adhesive layer 295, a cover member 155, a support substrate 145, a flexible circuit board 157, and a printed circuit board 160.

For example, the display apparatus 1000 can include a substrate 110. The substrate 110 can be a member for supporting other components of the display apparatus 1000. The substrate 110 can be formed of an insulation material. For example, the substrate 110 can be formed of glass, a resin, etc. In addition, the substrate 110 can be formed of a flexible material. For example, the substrate 110 can be made of a flexible plastic material, such as polyimide (PI). However, the embodiments of the present disclosure are not limited thereto.

The display panel 100 can implement information, video, and/or image provided to a user. For example, the display panel 100 can include an display area AA (or active area) and a non-display area NA (or non-active area). For example, the substrate 110 can include the display area AA and the non-display area NA. The non-display area NA can surround the display area AA entirely or only in part(s). Descriptions of the display area AA and the non-display area NA are not limited to the substrate 110, but descriptions thereof can be made with respect to the display apparatus 1000.

The display area AA can be an area on which an image is displayed. The display area AA can include a plurality of pixels PX. Each of the plurality of pixels PX can be formed of a plurality of sub-pixels. A plurality of light-emitting elements can be disposed in each of the plurality of sub-pixels. A plurality of light-emitting elements can be configured differently according to the type of the display apparatus 1000. For example, when the display apparatus 1000 is an inorganic light-emitting display apparatus, the light-emitting element can be a light-emitting diode (LED), a micro LED, or a mini LED, but the embodiments of the present disclosure are not limited thereto.

The non-display area NA can be an area on which no image is displayed. Various lines, circuits, and the like for driving the plurality of pixels PX of the display area AA can be disposed on the non-display area NA. For example, in the non-display area NA, various lines and driving circuits can be mounted, and a pad part PAD to which an integrated circuit, a printed circuit, and the like are connected can be disposed, but the embodiments of the present disclosure are not limited thereto.

For example, the driving circuit can be a data driving circuit and/or a gate driving circuit, but the embodiments of the present disclosure are not limited thereto. Lines for supplying control signals for controlling driving circuits can be disposed. For example, the control signals can include various types of timing signals including a clock signal, an input data enable signal, and synchronization signals, but the embodiments of the present disclosure are not limited thereto. The control signals can be received through the pad part PAD. For example, link lines LL for transmitting signals can be disposed in the non-display area NA. For example, driving components, such as a flexible circuit board 157 and a printed circuit board 160, can be connected to the pad part PAD.

According to aspects of the present disclosure, the non-display area NA can include a first non-display area NA1, a bending area BA, and a second non-display area NA2. For example, the first non-display area NA1 can be an area that surrounds at least a part of the display area AA. The bending area BA can be an area extending from at least one of a plurality of sides of the first non-display area NA1 and can be a bendable area. The second non-display area NA2 can be an area extending from the bending area BA and can have the pad part PAD disposed therein. For example, the bending area BA can be bent, and the remaining area of the substrate 110 not including the bending area BA can be flat. In this case, as the bending area BA is bent, the second non-display area NA2 can be located on a rear surface of the display area AA. However, the embodiments of the present disclosure are not limited thereto.

The display area AA of the substrate 110 or the display apparatus 1000 can be configured in various shapes according to the design of the display apparatus 1000. For example, the display area AA can be formed in a rectangular shape with four rounded corners, but the embodiments of the present disclosure are not limited thereto. As another example, the display area AA can be formed in a rectangular shape with four right-angled corners, a circular shape, etc., but the embodiments of the present disclosure are not limited thereto.

According to aspects of the present disclosure, a width of the second non-display area NA2 in which a plurality of pad electrodes PE are disposed can be greater than a width of the bending area BA in which only the plurality of link lines LL are disposed. In addition, a width of the display area AA in which the plurality of sub-pixels are disposed can be greater than the width of the bending area BA in which only the plurality of link lines LL are disposed. In the drawings, the width of the bending area BA is illustrated as being narrower than widths of other areas of the substrate 110, but the shape of the substrate 110 including the bending area BA is illustrative, and the embodiments of the present disclosure are not limited thereto.

Referring to FIG. 3, a plurality of pixel driving circuits PD can be disposed in the display area AA. The plurality of pixel driving circuits PD can be circuits for driving the light-emitting elements of the plurality of sub-pixels. Each of the plurality of pixel driving circuits PD can include a plurality of transistors including a driving transistor, a storage capacitor, etc., and supply control signals, power, and a driving current to the light-emitting elements of the plurality of sub-pixels in order to control the light-emitting operation of the plurality of light-emitting elements. For example, the pixel driving circuit PD can include a power line and a signal line for controlling light-emitting on/off and/or light-emitting time of the light-emitting element. For example, the plurality of pixel driving circuits PD can be driving drivers manufactured using a process of manufacturing a metal-oxide-silicon field effect transistor (MOSFET) on a semiconductor substrate, but the embodiments of the present disclosure are not limited thereto. The driving driver can include the plurality of pixel driving circuits PD and drive the plurality of sub-pixels. For example, the plurality of pixel driving circuits PD can include micro drivers μDriver, but the embodiments of the present disclosure are not limited thereto. For example, the plurality of pixel driving circuits PD can include driver chips, but the embodiments of the present disclosure are not limited thereto.

Referring to FIG. 1 again, the flexible circuit board 157 and the printed circuit board 160 can be disposed below the display panel 100. The flexible circuit board 157 and the printed circuit board 160 can be disposed at at least one edge of the display panel 100, but the embodiments of the present disclosure are not limited thereto. One side of the flexible circuit board 157 can be attached to the display panel 100, and the other side can be attached to the printed circuit board 160, but the embodiments of the present disclosure are not limited thereto. The flexible circuit board 157 can be a flexible film, but the embodiments of the present disclosure are not limited thereto.

The pad part PAD including the plurality of pad electrodes PEs can be disposed in the second non-display area NA2. A driving component including one or more flexible circuit boards (or flexible films) 157 and the printed circuit board 160 can be attached or bonded to the pad part PAD. The plurality of pad electrodes PEs of the pad part PAD can be electrically connected to one or more flexible circuit boards (or flexible films) 157, and various signals (or power) from the printed circuit board 160 and the flexible circuit board (or the flexible film) 157 can be transmitted to the plurality of pixel driving circuits PDs of the display area AA.

The flexible circuit board (or the flexible film) 157 can be a film in which various types of components are disposed on a flexible base film. For example, a drive IC, such as a gate driver IC or a data driver IC, can be disposed on the flexible circuit board (or the flexible film) 157, but the embodiments of the present disclosure are not limited thereto. The drive IC can be a component for processing data and driving signals for displaying an image. The drive IC can be disposed by a method of a chip on glass (COG), a chip on film (COF), a tape carrier package (TCP), etc. according to a mounting method, but the embodiments of the present disclosure are not limited thereto. The flexible circuit board (or the flexible film) 157 can be attached or bonded to the plurality of pad electrodes PE through a conductive adhesive layer, but the embodiments of the present disclosure are not limited thereto.

The printed circuit board 160 can be a component that is electrically connected to one or more flexible circuit boards (or flexible films) 157 and supplies signals to the drive IC. The printed circuit board 160 can be disposed at one side of the flexible circuit board (or the flexible film) 157 and electrically connected to the flexible circuit board (or the flexible film) 157. Various types of components for supplying various signals to the drive IC can be disposed on the printed circuit board 160. For example, various components, such as a timing controller, a power supply, a memory, a processor, etc. can be disposed on the printed circuit board 160. For example, the printed circuit board 160 can include a power management integrated circuit (PMIC), but the embodiments of the present disclosure are not limited thereto.

The printed circuit board 160 can include at least one hole 180, but the embodiments of the present disclosure are not limited thereto. An internal component for detecting ambient light, temperature, and the like that can be provided to a plurality of sensors can be disposed in an area corresponding to the at least one hole 180. For example, the internal component can include an ambient light sensor (ALS), a temperature sensor, etc., but the embodiments of the present disclosure are not limited thereto. For example, the hole 180 can be a transmissive hole or the like, but the embodiments of the present disclosure are not limited thereto.

Referring to FIG. 1, the polarizing layer 293 can be disposed on the display panel 100. The polarizing layer 293 can prevent or reduce light generated from an external light source from entering the display panel 100 and affecting the light-emitting element and the like.

The cover member 155 can be disposed on the polarizing layer 293. The cover member 155 can be a member for protecting the display panel 100. The adhesive layer 295 can be disposed between the polarizing layer 293 and the cover member 155. The cover member 155 can be attached to the display panel 100 by the adhesive layer 295. The adhesive layer 295 can include an optically clear adhesive (OCA), an optically clear resin (OCR), a pressure sensitive adhesive (PSA), etc., but the embodiments of the present disclosure are not limited thereto.

The support substrate 145 can be disposed between the display panel 100 and the printed circuit board 160. The support substrate 145 can reinforce the rigidity of the display panel 100. The support substrate 145 can be a backplate, but the embodiments of the present disclosure are not limited thereto.

Referring to FIGS. 1 to 3, the plurality of link lines LL can be disposed in the non-display area NA. The plurality of link lines LL can be lines that transmit various types of signals from the one or more flexible circuit boards (or flexible films) 157 and the printed circuit board 160 to the display area AA. The plurality of link lines LLs can extend from the plurality of pad electrodes PEs of the second non-display area NA2 toward the bending area BA and the first non-display area NA1 and can be electrically connected to a plurality of driving lines VLs of the display area AA. The plurality of pixel driving circuits PD can be driven by receiving signals from the one or more flexible circuit boards (or flexible films) 157 and the printed circuit board 160 through the driving lines VL of the display area AA and the link lines LL of the non-display area NA.

For example, the plurality of driving lines VL along with the plurality of link lines LL can be lines for transmitting the signals output from the flexible circuit boards (or the flexible films) 157 and the printed circuit board 160 to the plurality of pixel driving circuits PD. The plurality of driving lines VL can be disposed in the display area AA and electrically connected to the plurality of pixel driving circuits PD, respectively. The plurality of driving lines VL can extend from the display area AA toward the non-display area NA and can be electrically connected to the plurality of link lines LL. Accordingly, the signals output from the flexible circuit boards (or the flexible films) 157 and the printed circuit board 160 can be transmitted to the plurality of pixel driving circuits PD through the plurality of link lines LL and the plurality of driving lines VL, respectively.

As the bending area BA is bent, parts of the plurality of link lines LL can also be bent. Since stress is concentrated on the bent parts of the bent link lines LL, cracks can occur in the link lines LL. Accordingly, the plurality of link lines LL can be formed of an excellent flexible conductive material to reduce cracks when the bending area BA is bent. For example, the plurality of link lines LL can be formed of an excellent flexible conductive material, such as gold (Au), silver (Ag), aluminum (Al), etc., but the embodiments of the present disclosure are not limited thereto. In addition, the plurality of link lines LL can be formed of one of various conductive materials used in the display area AA. For example, the plurality of link lines LL can be formed of molybdenum (Mo), chromium (Cr), titanium (Ti), nickel (Ni), neodymium (Nd), copper (Cu), and an alloy of silver (Ag) and magnesium (Mg), or an alloy thereof, but the embodiments of the present disclosure are not limited thereto. The plurality of link lines LL can be formed of a multilayered structure including various conductive materials. For example, the plurality of link lines LL can be formed of a triple layer structure of titanium (Ti)/aluminum (Al)/titanium (Ti), but the embodiments of the present disclosure are not limited thereto.

The plurality of link lines LLs can be formed in various shapes to reduce stress. At least some of the plurality of link lines LL disposed on the bending area BA can extend in the same direction as an extension direction of the bending area BA or extend in a different direction from the extension direction of the bending area BA to reduce stress. For example, when the bending area BA extends in one direction from the first non-display area NA1 to the second non-display area NA2, at least some of the link lines LL disposed on the bending area BA can extend in a direction oblique to the one direction. For another example, the at least some of the plurality of link lines LL can be formed as patterns of various shapes. For example, the at least some of the plurality of link lines LL disposed on the bending area BA can have a shape in which a conductive pattern having at least one of a diamond shape, a rhombus shape, a trapezoidal wave shape, a triangular wave shape, a sawtooth wave shape, a sine wave shape, a circular shape, and an omega ((2) shape is repeatedly disposed, but the embodiments of the present disclosure are not limited thereto. Accordingly, to minimize the stress concentrated on the plurality of link lines LL and cracks caused by the stress, the shapes of the plurality of link lines LL can be formed in various shapes including the above shapes, but the embodiments of the present disclosure are not limited thereto.

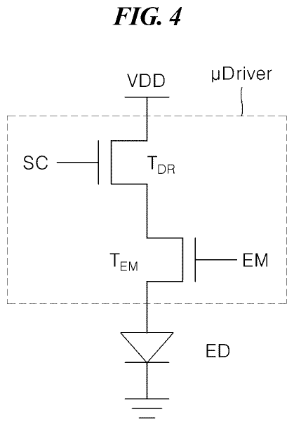

FIG. 4 is a view illustrating a circuit structure according to an embodiment of the present disclosure.

Particularly, FIG. 4 illustrates an example in which one light-emitting element ED is connected to the micro driver μDriver, but the embodiments of the present disclosure are not limited thereto. For example, eight light-emitting elements ED can be connected to one micro driver μDriver. As another example, 16 light-emitting elements ED can be connected to one micro driver μDriver, or 32 light-emitting elements ED or 64 light-emitting elements ED can be connected to one micro driver μDriver simultaneously. The light-emitting element ED can be a micro light emitting element (μLED).

Referring to FIG. 4, one micro driver μDriver can include a driving transistor T_{DR} and a light-emitting transistor T_{EM}, but the embodiments of the present disclosure are not limited thereto.

For example, the driving transistor T_{DR} can have a first electrode to which a high-potential power voltage VDD applied, a second electrode to which a first electrode of the light-emitting transistor T_{EM} is connected, and a gate electrode to which a scan signal SC is applied. The scan signal SC applied to the gate electrode of the driving transistor T_{DR} is DC power, and a fixed reference voltage (Vref) can be applied for each frame, but the embodiments of the present disclosure are not limited thereto.

The light-emitting transistor T_{EM} can have a first electrode to which the second electrode of the driving transistor T_{DR} is connected, a second electrode to which the light-emitting element ED is connected, and a gate electrode to which a light-emitting signal EM is applied. The light-emitting signal EM applied to the gate electrode of the light-emitting transistor T_{EM} can be a pulse width modulation (PWM) signal that varies for each frame, but the embodiments of the present disclosure are not limited thereto.

The light-emitting element ED can have a first electrode connected to the second electrode of the light-emitting transistor T_{EM} and the second electrode connected to the ground. For example, the first electrode can be an anode electrode, and the second electrode can be a cathode electrode, but the embodiments of the present disclosure are not limited thereto.

The driving transistor T_{DR} and the light-emitting transistor T_{EM} can each be an n-type transistor or a p-type transistor.

The micro driver μDriver can turn on the driving transistor T_{DR} by the scan signal SC applied from a timing controller (T-CON) and turn on the light-emitting transistor T_{EM} by the light-emitting signal EM. Accordingly, a driving current can be applied to the light-emitting element ED via the driving transistor T_{DR} and the light-emitting transistor T_{EM} by the high-potential power voltage VDD applied to the first electrode of the driving transistor T_{DR} so that the light-emitting element ED can emit light.

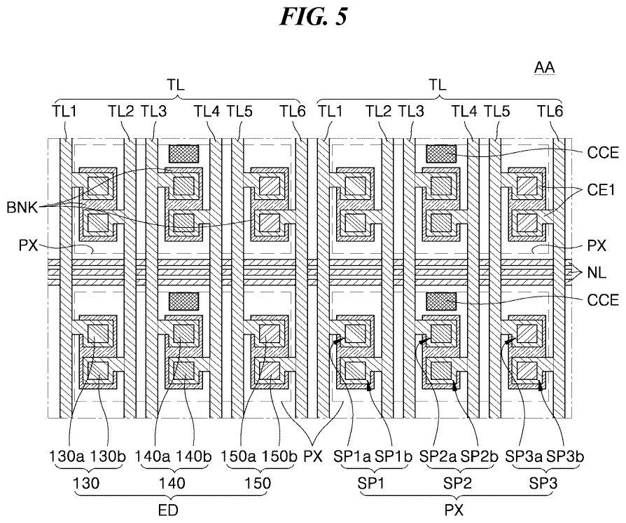

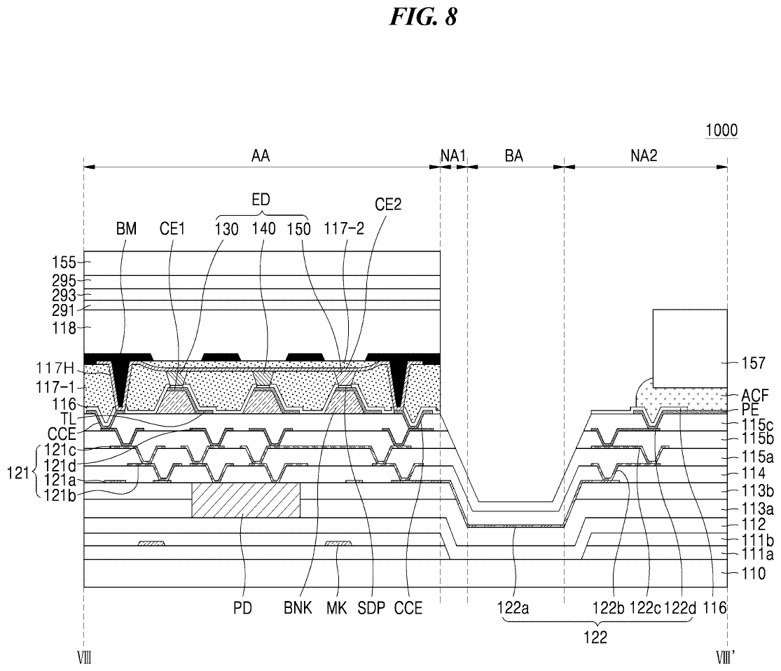

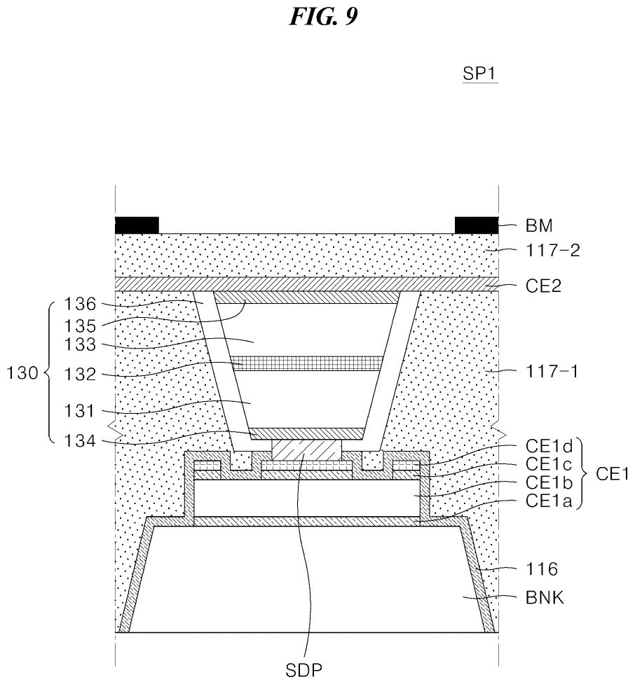

FIGS. 5 to 7 are plan views of the display apparatus according to the embodiment of the present disclosure. FIGS. 8 and 9 are cross-sectional views of the display apparatus according to one embodiment of the present disclosure.

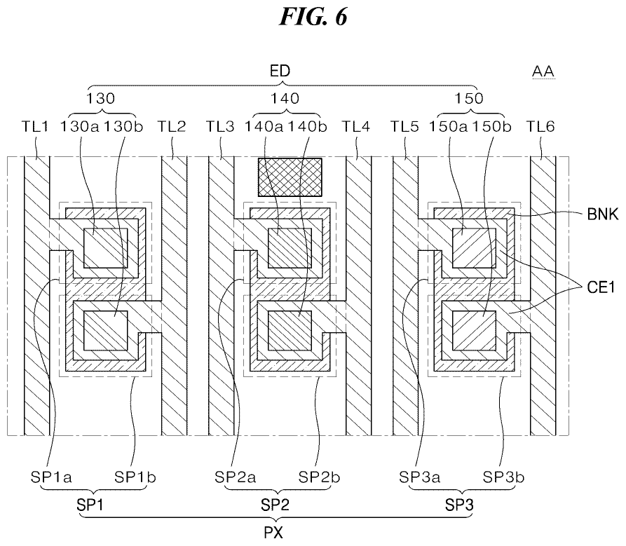

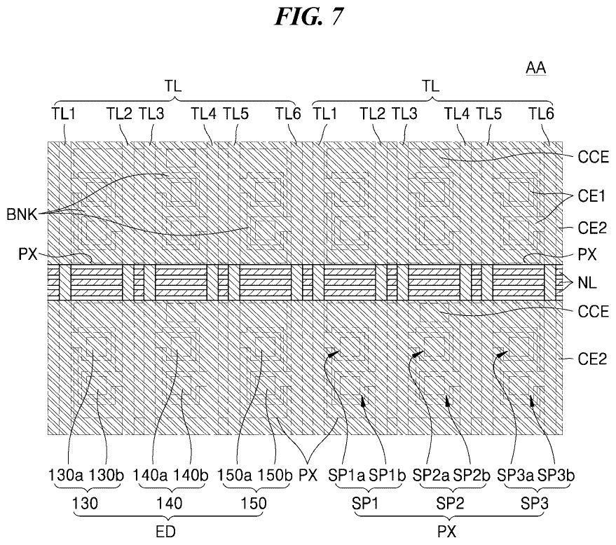

For example, FIG. 5 is an enlarged plan view of a display area including a plurality of pixels. For example, FIG. 6 is an enlarged plan view of a display area including one pixel. For example, FIG. 7 is an enlarged plan view of a display area including a plurality of pixels. For example, FIG. 8 is a cross-sectional view of the display area AA, the first non-display area NA1, the bending area BA, and the second non-display area NA2. For example, FIG. 9 is a cross-sectional view of a display area including one sub-pixel SP1. FIG. 8 is a cross-sectional view of the display apparatus along line VIII-VIII′ in FIG. 3. For convenience of illustration, FIG. 3 illustrates line VIII-VIII′ that does not overlap the driving line VL and the link line LL, but line VIII-VIII′ of FIG. 3 is intended to indicate the same location as an adjacent driving line VL and link line LL.

FIGS. 5 and 6 illustrate a plurality of signal lines TL, a plurality of communication lines NL, a plurality of first electrodes CE1, a plurality of banks BNK, and a plurality of light-emitting elements ED, but the embodiments of the present disclosure are not limited thereto. FIG. 7 is an enlarged plan view of FIG. 5 in which a plurality of second electrodes CE2 are additionally disposed.

Referring to FIGS. 5, 6, 7, and 9, the plurality of pixels PX formed of a plurality of sub-pixels can be disposed in the display area AA. Each of the plurality of sub-pixels can include the light-emitting element ED and independently emit light. The plurality of sub-pixels can be disposed in a matrix form that is formed of a plurality of rows and a plurality of columns, but the embodiments of the present disclosure are not limited thereto.

The plurality of sub-pixels can include a first sub-pixel SP1, a second sub-pixel SP2, and a third sub-pixel SP3. For example, one of the first sub-pixel SP1, the second sub-pixel SP2, and the third sub-pixel SP3 can be a red sub-pixel, another can be a green sub-pixel, and the remaining one can be a blue sub-pixel. The types of the plurality of sub-pixels are illustrative, and the embodiments of the present disclosure are not limited thereto.

Each of the plurality of pixels PX can include one or more first sub-pixels SP1, one or more second sub-pixels SP2, and one or more third sub-pixels SP3. For example, one pixel PX can include one pair of first sub-pixels SP1, one pair of second sub-pixels SP2, and one pair of third sub-pixels SP3. The pair of first sub-pixels SP1 can be formed of a 1-1 sub-pixel SP1a and a 1-2 sub-pixel SP1b. The pair of second sub-pixels SP2 can be formed of a 2-1 sub-pixel SP2a and a 2-2 sub-pixel SP2b. The pair of third sub-pixels SP3a can be formed of a 3-1 sub-pixel SP3a and a 3-2 sub-pixel SP3b. For example, one pixel PX can include the 1-1 sub-pixel SP1a and the 1-2 sub-pixel SP1b, the 2-1 sub-pixel SP2a and the 2-2 sub-pixel SP2b, and the 3-1 sub-pixel SP3a and the 3-2 sub-pixel SP3b, but the embodiments of the present disclosure are not limited thereto.

The plurality of sub-pixels forming one pixel PX can be arranged in various ways. For example, in one pixel PX, a pair of first sub-pixels SP1 can be disposed in the same column, a pair of second sub-pixels SP2 can be disposed in the same column, and a pair of third sub-pixels SP3 can be disposed in the same column. The first sub-pixel SP1, the second sub-pixel SP2, and the third sub-pixel SP3 can be disposed in the same row. The number and arrangement of plurality of sub-pixels forming one pixel PX are illustrative, and the embodiments of the present disclosure are not limited thereto.

The plurality of signal lines TL can be disposed in an area between the plurality of sub-pixels. The plurality of signal lines TL can extend in a column direction between the plurality of sub-pixels. The plurality of signal lines TL can be lines that transmit an anode voltage output from the pixel driving circuit PD to the plurality of sub-pixels. For example, the plurality of signal lines TL can be electrically connected to the plurality of pixel driving circuits PD and the first electrodes CE1 of the plurality of sub-pixels. The anode voltage output from the pixel driving circuit PD can be transmitted to the first electrodes CE1 of the plurality of sub-pixels through the plurality of signal lines TL. For example, the first electrode CE1 can be an electrode that is electrically connected to an anode electrode 134 of the light-emitting element ED. Accordingly, the anode voltage from the signal line TL can be transmitted to the anode electrode 134 of the light-emitting element ED through the first electrode CE1.

Accordingly, the structure of the display apparatus 1000 can be simplified using the pixel driving circuit PD in which a plurality of pixel circuits are integrated instead of forming a plurality of transistors and storage capacitors in each of the plurality of sub-pixels. In addition, since circuits disposed in each of the plurality of sub-pixels are integrated in one pixel driving circuit PD, high-efficiency, low-power driving can be made possible.

The plurality of signal lines TL can include a first signal line TL1, a second signal line TL2, a third signal line TL3, a fourth signal line TL4, a fifth signal line TL5, and a sixth signal line TL6. The first signal line TL1 and the second signal line TL2 can be electrically connected to the pair of first sub-pixels SP1, respectively. The third signal line TL3 and the fourth signal line TLA can be electrically connected to the pair of second sub-pixels SP2, respectively. The fifth signal line TL5 and the sixth signal line TL6 can be electrically connected to the pair of third sub-pixels SP3, respectively.

The first signal line TL1 can be disposed at one sides of the pair of first sub-pixels SP1, and the second signal line TL1 can be disposed at the other sides of the pair of first sub-pixels SP1. The first signal line TL1 can be electrically connected to the first electrode CE1 of one of the pair of first sub-pixels SP1, for example, the 1-1 sub-pixel SP1a. The second signal line TL2 can be electrically connected to the first electrode CE1 of the other of the pair of first sub-pixels SP1, for example, the 1-2 sub-pixel SP1b.

The third signal line TL3 can be disposed at one sides of the pair of second sub-pixels SP2, and the fourth signal line TLA can be disposed at the other sides of the pair of second sub-pixels SP2. For example, the third signal line TL3 can be disposed adjacent to the second signal line TL2. The third signal line TL3 can be electrically connected to the first electrode CE1 of one of the pair of second sub-pixels SP2, for example, the 2-1 sub-pixel SP2a. The fourth signal line TLA can be electrically connected to the first electrode CE1 of the other of the pair of second sub-pixels SP2, for example, the 2-2 sub-pixel SP2b.

The fifth signal line TL5 can be disposed at one sides of the pair of third sub-pixels SP3, and the sixth signal line TL6 can be disposed at the other sides of the pair of third sub-pixels SP3. For example, the fifth signal line TL5 can be disposed adjacent to the fourth signal line TLA. The sixth signal line TL6 can be disposed adjacent to the first signal line TL1 connected to a neighboring pixel PX. The fifth signal line TL5 can be electrically connected to the first electrode CE1 of one of the pair of third sub-pixels SP3, for example, the 3-1 sub-pixel SP3a. The sixth signal line TL6 can be electrically connected to the first electrode CE1 of the other of the pair of third sub-pixels SP3, for example, the 3-2 sub-pixel SP3b.

The plurality of signal lines TL can be formed of a conductive material. For example, the plurality of signal lines TL can be formed in a single structure or a multilayered structure including a conductive material, such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), etc., but the embodiments of the present disclosure are not limited thereto.

Referring to FIG. 7, the plurality of communication lines NL can be disposed in an area between the plurality of pixels PX. The plurality of communication lines NL can be disposed to extend in a row direction in the area between the plurality of pixels PX. The plurality of communication lines NL can be disposed in an area between a plurality of second electrodes CE2 and may not overlap the plurality of second electrodes CE2. For example, the plurality of communication lines NL can be lines used for short-range communication, such as near field communication (NFC). The plurality of communication lines NL can serve as antennas. For example, the plurality of communication lines NL can be a plurality of connection lines or the like, but the embodiments of the present disclosure are not limited thereto.

According to aspects of the present disclosure, the bank BNK can be disposed in each of the plurality of sub-pixels. The plurality of banks BNK can be structures on which the plurality of light-emitting elements ED are seated. The plurality of banks BNK can give guidance related to the locations of the plurality of light-emitting elements ED in a transfer process of transferring the plurality of light-emitting elements ED onto the display apparatus 1000. In the transfer process of the plurality of light-emitting elements ED, the plurality of light-emitting elements ED can be transferred onto the plurality of banks BNK. The plurality of banks BNK can be bank patterns, structures, etc., but the embodiments of the present disclosure are not limited thereto.

A bank BNK of the first sub-pixel SP1, a bank BNK of the second sub-pixel SP2, and a bank BNK of the third sub-pixel SP3 can be disposed to be spaced apart from each other. The bank BNK of the first sub-pixel SP1, the bank BNK of the second sub-pixel SP2, and the bank BNK of the third sub-pixel SP3 can be formed separately. Accordingly, the banks BNK of the first sub-pixel SP1, the second sub-pixel SP2, and the third sub-pixel SP3 onto which different types of light-emitting elements ED are transferred can be easily identified.

A bank BNK of the 1-1 sub-pixel SP1a and a bank BNK of the 1-2 sub-pixel SP1b can be connected and formed to be spaced apart from each other or formed separately. For example, considering the design of the transfer process requirements and the like, the bank BNK of the 1-1 sub-pixel SP1a and the bank BNK of the 1-2 sub-pixel SP1b in which the light-emitting element ED of the same type is disposed can be connected and formed to be spaced apart from each other or formed separately. In addition, a bank BNK of the 2-1 sub-pixel SP2a and a bank BNK of the 2-2 sub-pixel SP2b can be connected or formed to be spaced apart from each other or formed separately. A bank BNK of the 3-1 sub-pixel SP3a and a bank BNK of the 3-2 sub-pixel SP3b can be connected or formed to be spaced apart from each other or formed separately. Accordingly, the banks BNK of the pair of the first sub-pixels SP1, the banks BNK of the pair of the second sub-pixels SP2, and the banks BNK of the pair of the third sub-pixels SP3 can be formed in various ways, and the embodiments of the present disclosure are not limited thereto.

For example, the plurality of banks BNK can be formed of an organic insulation material. The plurality of banks BNK can be formed of a single layer or multiple layers of an organic insulation material. For example, the plurality of banks BNK can be formed of a photoresist, polyimide (PI), or acrylic-based material, but the embodiments of the present disclosure are not limited thereto.

The first electrode CE1 can be disposed in each of the plurality of sub-pixels. The first electrode CE1 can be disposed on the bank BNK. The first electrode CE1 can be electrically connected to one of the plurality of signal lines TL. At least a part of the first electrode CE1 can extend outward of the bank BNK and can be electrically connected to the signal line TL closest to the first electrode CE1. For example, a part of the first electrode CE1 of the 1-1 sub-pixel SP1a can extend to one area of the 1-1 sub-pixel SP1a and can be electrically connected to the first signal line TL1, and a part of the first electrode CE1 of the 1-2 sub-pixel SP1b can extend to the other area of the 1-2 sub-pixel SP1b and can be electrically connected to the second signal line TL2. A part of the first electrode CE1 of the 2-1 sub-pixel SP2a can extend to one area of the 2-1 sub-pixel SP2a and can be electrically connected to the third signal line TL3, and a part of the first electrode CE1 of the 2-2 sub-pixel SP2b can extend to the other area of the 2-2 sub-pixel SP2b and can be electrically connected to the fourth signal line TL4. A part of the first electrode CE1 of the 3-1 sub-pixel SP3a can extend to one area of the 3-1 sub-pixel SP3a and can be electrically connected to the fifth signal line TL5, and a part of the first electrode CE1 of the 3-2 sub-pixel SP3b can extend to the other area of the 3-2 sub-pixel SP3b and can be electrically connected to the sixth signal line TL6.

The first electrode CE1 can be electrically connected to the anode electrode 134 of the light-emitting element ED and can transmit the anode voltage from the pixel driving circuit PD to the light-emitting element ED through the signal line TL. A different voltage can be applied to the first electrode CE1 of each of the plurality of sub-pixels according to a video, which will be displayed. For example, a different voltage can be applied to the first electrode CE1 of each of the plurality of sub-pixels. Accordingly, the first electrode CE1 can be a pixel electrode, and the embodiments of the present disclosure are not limited thereto.

The first electrode CE1 can be formed of a conductive material. For example, the first electrodes CE1 can be formed integrally with the plurality of signal lines TL. For example, the first electrode CE1 can be formed of the same conductive material as the plurality of signal lines TL, but the embodiments of the present disclosure are not limited thereto. For example, the first electrode CE1 can be formed of a single layer structure or a multilayered structure of a conductive material, such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), etc., but the embodiments of the present disclosure are not limited thereto.

The light-emitting element ED can be disposed in each of the plurality of sub-pixels. The plurality of light-emitting elements ED can be one of an LED or a micro LED, but the embodiments of the present disclosure are not limited thereto. The plurality of light-emitting elements ED can be disposed on the bank BNK and the first electrode CE1. The plurality of light-emitting elements ED can be disposed on the first electrode CE1 and electrically connected to the first electrode CE1. Accordingly, the light-emitting element ED can receive the anode voltage from the pixel driving circuit PD through the signal line TL and the first electrode CE1 and emit light.

The plurality of light-emitting elements ED can include a first light-emitting element 130, a second light-emitting element 140, and a third light-emitting element 150. The first light-emitting element 130 can be disposed in the first sub-pixel SP1. The second light-emitting element 140 can be disposed in the second sub-pixel SP2. The third light-emitting element 150 can be disposed in the third sub-pixel SP3. For example, one of the first light-emitting element 130, the second light-emitting element 140, and the third light-emitting element 150 can be a red light-emitting element, another can be a green light-emitting element, and the remaining one can be a blue light-emitting element, but the embodiments of the present disclosure are not limited thereto. Accordingly, red light, green light, and blue light emitted from the plurality of light-emitting elements ED can be combined to implement various colors of light including white. The types of the plurality of light-emitting elements ED are illustrative, and the embodiments of the present disclosure are not limited thereto.

The first light-emitting element 130 can include a 1-1 light-emitting element 130a disposed in the 1-1 sub-pixel SP1a, and a 1-2 light-emitting element 130b disposed in the 1-2 sub-pixel SP1b. The second light-emitting element 140 can include a 2-1 light-emitting element 140a disposed in the 2-1 sub-pixel SP2a, and a 2-2 light-emitting element 140b disposed in the 2-2 sub-pixel SP2b. The third light-emitting element 150 can include a 3-1 light-emitting element 150a disposed in the 3-1 sub-pixel SP3a, and a 3-2 light-emitting element 150b disposed in the 3-2 sub-pixel SP3b.

Referring to FIGS. 5, 6, 7, and 9 together, the second electrode CE2 can be disposed in each of the plurality of sub-pixels. The second electrode CE2 can be disposed on the light-emitting element ED. The second electrode CE2 can be electrically connected to the pixel driving circuit PD through a plurality of contact electrodes CCE.

For example, the second electrode CE2 can be electrically connected to a cathode electrode 135 of the light-emitting element ED to transmit a cathode voltage from the pixel driving circuit PD to the light-emitting element ED. The same cathode voltage can be applied to the second electrode CE2 of each of the plurality of sub-pixels. For example, the same voltage can be applied to the second electrode CE2 of each of the plurality of sub-pixels and the cathode electrode 135 of the light-emitting element ED. Accordingly, the second electrode CE2 can be a common electrode, and the embodiments of the present disclosure are not limited thereto.

At least some of the plurality of sub-pixels can share the second electrode CE2. At least some of the second electrodes CE2 of the plurality of sub-pixels can be electrically connected. Since the same voltage is applied to the second electrodes CE2, the second electrodes CE2 of at least some sub-pixels can be shared and used. For example, the second electrodes CE2 of at least some pixels PX among the plurality of pixels PX disposed in the same row can be connected. For example, one second electrode CE2 can be disposed in each of the plurality of pixels PX. One second electrode CE2 can be disposed per n sub-pixels.

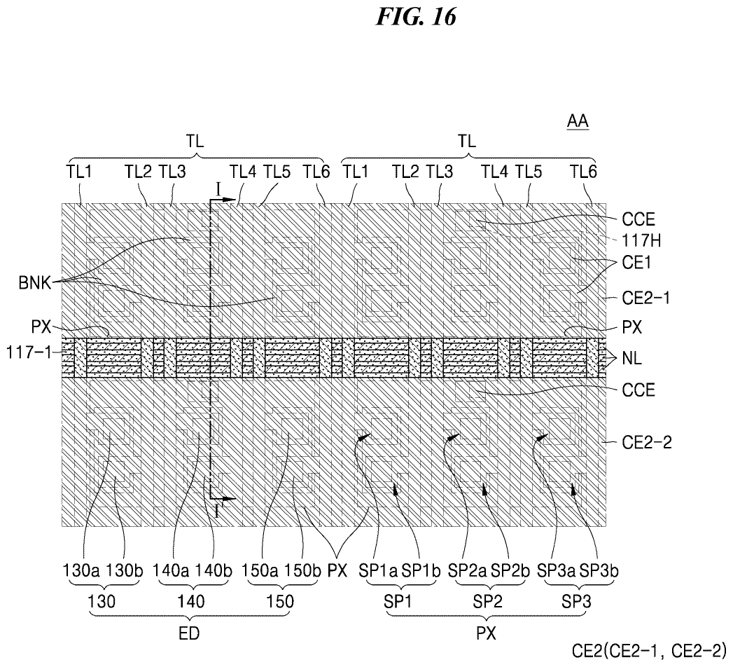

For example, some of the second electrodes CE2 of the plurality of sub-pixels can be disposed to be spaced apart from each other or disposed separately. For example, second electrodes CE2 connected to pixels PX in an n^{th} row and second electrodes CE2 connected to pixels PX in an (n+1)^{th} row can be disposed to be spaced apart from each other or disposed separately. For example, the plurality of second electrodes CE2 can be disposed to be spaced apart from each other with the plurality of communication lines NL extending in the row direction interposed therebetween. The description thereof will be given below in FIG. 16. Accordingly, the number of plurality of sub-pixels can be more than the number of plurality of second electrodes CE2. As another example, all of the second electrodes CE2 of the plurality of sub-pixels can be connected so that only one second electrode CE2 can be disposed on the substrate 110, and the embodiments of the present disclosure are not limited thereto.

The plurality of second electrodes CE2 can be formed of a transparent conductive material, but the embodiments of the present disclosure are not limited thereto. The plurality of second electrodes CE2 can be formed of a transparent conductive material so that light emitted from the light-emitting element ED can emit upward of the second electrodes CE2. For example, the second electrode CE2 can be formed of a transparent conductive material, such as indium tin oxide (ITO), indium zinc oxide (IZO), indium gallium zinc oxide (IGZO), etc., but the embodiments of the present disclosure are not limited thereto.

The plurality of contact electrodes CCE can be disposed on the substrate 110. For example, the plurality of contact electrodes CCE can be disposed to be spaced apart from the plurality of banks BNK and the plurality of signal lines TL. Each of the plurality of second electrodes CE2 can overlap at least one contact electrode CCE. For example, one second electrode CE2 can overlap the plurality of contact electrodes CCE.

For example, the plurality of contact electrodes CCE can be electrically connected to the plurality of second electrodes CE2. The plurality of contact electrodes CCE can be disposed between the substrate 110 and the plurality of second electrodes CE2 to transmit the cathode voltage from the pixel driving circuit PD to the second electrode CE2.

For example, when a micro LED is used as the light-emitting element ED, the display apparatus 1000 can be manufacturing by forming a plurality of micro LED on a wafer and transferring the micro LED onto the substrate 110 of the display apparatus 1000. During the process of transferring the plurality of light-emitting elements ED having a micro size from the wafer onto the substrate 110, various types of defects can occur. For example, a non-transfer defect in which the light-emitting element ED is not transferred can occur in some sub-pixels, and a defect in which the light-emitting element ED is transferred out of a correct location due to an alignment error can occur in other sub-pixels. In addition, the transfer process can be performed normally, but the transferred light-emitting element ED can be defective. Accordingly, in consideration of defects during the transfer process of the plurality of light-emitting elements ED, the plurality of light-emitting elements ED of the same type can be transferred onto one sub-pixel. A lighting test of the plurality of light-emitting elements ED can be performed, and only one light-emitting element ED that is ultimately determined to be normal can be used.

For example, both the 1-1 light-emitting element 130a and the 1-2 light-emitting element 130b can be transferred onto one pixel PX, and whether the 1-1 light-emitting element 130a and the 1-2 light-emitting element 130b are defective can be tested. When it is determined that both the 1-1 light-emitting element 130a and the 1-2 light-emitting element 130b are normal, only the 1-1 light-emitting element 130a can be used, and the 1-2 light-emitting element 130b may not be used. For another example, when it is determined that only the 1-2 light-emitting element 130b among the 1-1 light-emitting element 130a and the 1-2 light-emitting element 130b are normal, the 1-1 light-emitting element 130a is not used, and only the 1-2 light-emitting element 130b can be used. Accordingly, even when the plurality of light-emitting elements ED of the same type are transferred onto one pixel PX, only one light-emitting element ED can be eventually used.

Accordingly, one of the pair of light-emitting elements ED can be a main (or primary) light-emitting element ED, and the other can be a redundancy light-emitting element ED. The redundancy light-emitting element ED can be a spare light-emitting element ED transferred in preparation of a defect of the main light-emitting element ED. When the main light-emitting element ED is defective, the defective main light-emitting element ED can be replaced with the redundancy light-emitting element ED and used. Accordingly, by transferring both the main light-emitting element ED and the redundancy light-emitting element ED onto one pixel PX, it is possible to minimize the degradation of display quality due to the defects of the main light-emitting element ED and the redundancy light-emitting element ED.

For example, the 1-1 light-emitting element 130a, the 2-1 light-emitting element 140a, and the 3-1 light-emitting element 150a that are transferred onto one pixel PX can be used as the main light-emitting element ED, and the 1-2 light-emitting element 130b, the 2-2 light-emitting element 140b, and the 3-2 light-emitting element 150b can be used as the redundancy light-emitting element ED. For example, the 1-1 light-emitting element 130a, the 2-2 light-emitting element 140b, and the 3-1 light-emitting element 150a can be used as the main light-emitting element ED, and the 1-2 light-emitting element 130b, the 2-1 light-emitting element 140a, and the 3-2 light-emitting element 150b can be used as the redundancy light-emitting element ED.

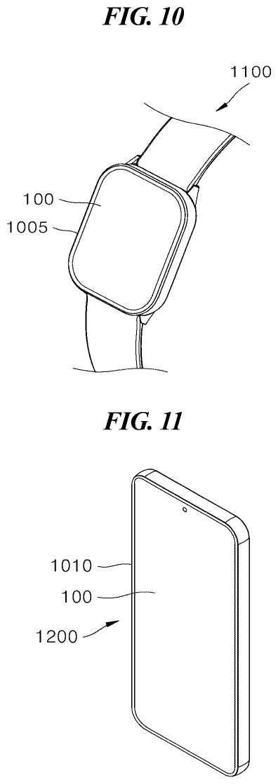

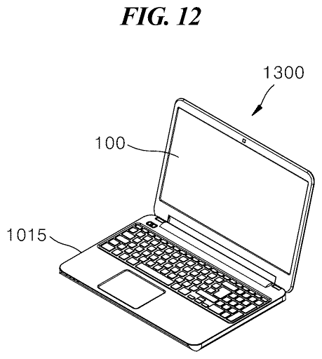

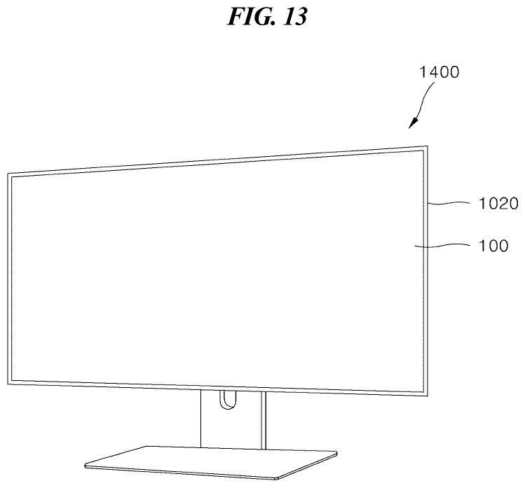

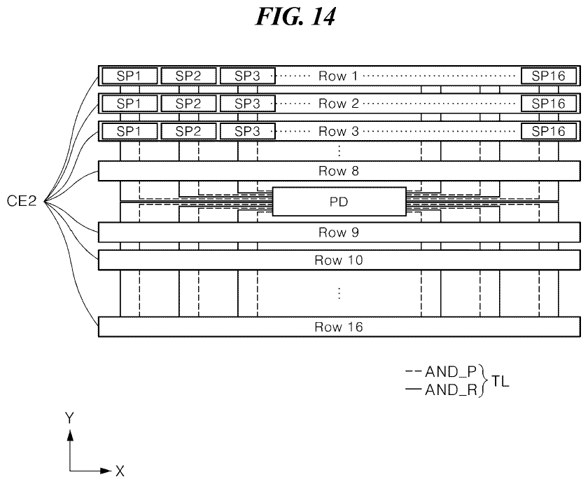

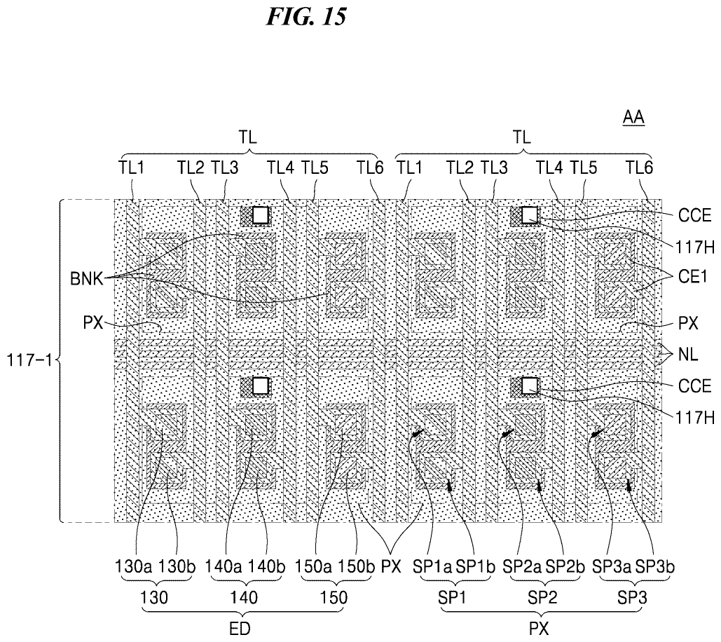

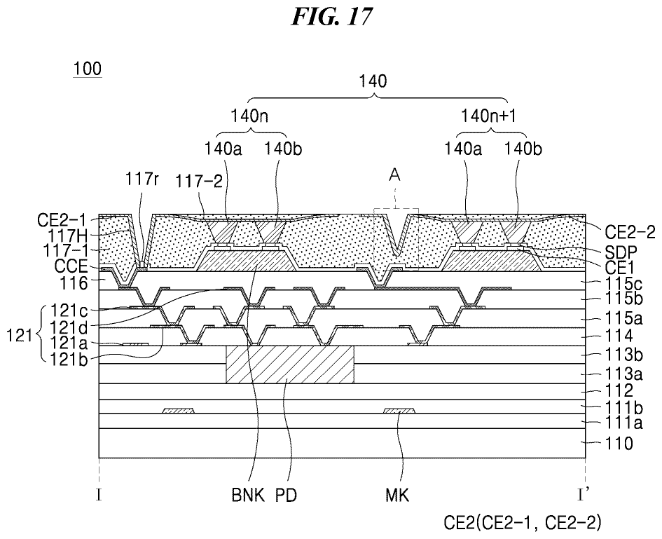

FIG. 8 is a cross-sectional view of the display apparatus according to one embodiment of the present disclosure. FIG. 9 is a cross-sectional view of the display apparatus according to the embodiment of the present disclosure. FIGS. 10 to 13 are views illustrating an apparatus to which the display apparatus according to the embodiments of the present disclosure is applied. FIG. 14 is a plan view illustrating an area in which one of a plurality of pixel driving circuits is disposed. FIGS. 15 and 16 are plan views of the display apparatus according to one embodiment of the present disclosure. FIG. 17 is a cross-sectional view along line I-I′ in FIG. 16. For example, FIG. 8 is a cross-sectional view of the display area AA, the first non-display area NA1, the bending area BA, and the second non-display area NA2. For example, FIG. 9 is a cross-sectional view of a display area including one sub-pixel SP1. For example, FIG. 15 is a partial enlarged plan view of a display area in which an optical layer 117-1 is disposed. For example, FIG. 16 is a partial enlarged plan view of an active area in which the second electrode CE2 is disposed. For convenience of description, FIG. 17 illustrates the second light-emitting element 140 as an example, but the embodiments of the present disclosure are not limited thereto.

Referring to FIG. 8, a first buffer layer 111a and a second buffer layer 111b can be disposed in the remaining area of the substrate 110 not including the bending area BA.

The first buffer layer 111a and the second buffer layer 111b can be disposed in the display area AA, the first non-display area NA1, and the second non-display area NA2. The first buffer layer 111a and the second buffer layer 111b can reduce the penetration of moisture or impurities into the substrate 110. The first buffer layer 111a and the second buffer layer 111b can be formed of an inorganic insulation material. For example, the first buffer layer 111a and the second buffer layer 111b can be formed of a single layer or multiple layers of silicon oxide (SiOₓ) or silicon nitride (SiNₓ), but the embodiments of the present disclosure are not limited thereto.

For example, parts of the first buffer layer 111a and the second buffer layer 111b on the bending area BA can be removed. An upper surface of the substrate 110 located in the bending area BA can be exposed from the first buffer layer 111a and the second buffer layer 111b. By removing the first buffer layer 111a and the second buffer layer 111b, which are formed of an inorganic insulation material, from the bending area BA, it is possible to minimize cracks in the first buffer layer 111a and the second buffer layer 111b, which can occur during bending.

A plurality of alignment keys MK can be disposed between the first buffer layer 111a and the second buffer layer 111b. The plurality of alignment keys MK can be formed to identify the location of the pixel driving circuit PD during the manufacturing process of the display apparatus 1000. For example, the plurality of alignment keys MK can be formed to align the location of the pixel driving circuit PD transferred onto the adhesive layer 112. As another example, the plurality of alignment keys MK can be omitted.

The adhesive layer 112 can be disposed on the second buffer layer 111b. The adhesive layer 112 can be disposed in the display area AA, the first non-display area NA1, the bending area BA, and the second non-display area NA2. As another example, at least a part of the adhesive layer 112 can be removed from the non-display area NA including the bending area BA. For example, the adhesive layer 112 can be formed of one of an adhesive polymer, an epoxy resin, a UV-curable resin, a polyimide-based material, an acrylate-based material, a urethane-based material, and a polydimethylsiloxane (PDMS), but the embodiments of the present disclosure are not limited thereto.

The pixel driving circuit PD can be disposed on the adhesive layer 112 in the display area AA. When the pixel driving circuit PD is implemented as a driving driver, the driving driver can be mounted on the adhesive layer 112 by a transfer process, but the embodiments of the present disclosure are not limited thereto.

A first protective layer 113a and a second protective layer 113b can be disposed on the adhesive layer 112 and the pixel driving circuit PD. The first protective layer 113a and the second protective layer 113b can be disposed to surround side surfaces of the pixel driving circuit PD, but the embodiments of the present disclosure are not limited thereto. For example, the second protective layer 113b can be disposed to cover at least a part of the upper surface of the pixel driving circuit PD. For example, at least one of the first protective layer 113a and the second protective layer 113b that are disposed on the bending area BA can be omitted. For example, the first protective layer 113a can be entirely disposed in the display area AA and the non-display area NA, and a part of the second protective layer 113b can be disposed in the display area AA, the first non-display area NA1, and the second non-display area NA2. For example, a part of the second protective layer 113b in the bending area BA can be removed. However, the embodiments of the present disclosure are not limited thereto.

The first protective layer 113a and the second protective layer 113b can be formed of an organic insulation material, but the embodiments of the present disclosure are not limited thereto. For example, the first protective layer 113a and the second protective layer 113b can be formed of a photoresist, polyimide (PI), or photo acryl-based material, but the embodiments of the present disclosure are not limited thereto. For example, the first protective layer 113a and the second protective layer 113b can be an overcoating layer or an insulating layer, but the embodiments of the present disclosure are not limited thereto.

According to aspects of the present disclosure, a plurality of first connection lines 121 can be disposed on the second protective layer 113b in the display area AA. The plurality of first connection lines 121 can be lines for electrically connecting the pixel driving circuit PD to other components. For example, the pixel driving circuit PD can be electrically connected to the plurality of signal lines TL, the plurality of contact electrodes CCE, and the like through the plurality of first connection lines 121. For example, the plurality of first connection lines 121 can include a 1-1 connection line 121a, a 1-2 connection line 121b, a 1-3 connection line 121c, and a 1-4 connection line 121d, but the embodiments of the present disclosure are not limited thereto.

For example, the plurality of 1-1 connection lines 121a can be disposed on the second protective layer 113b. The plurality of 1-1 connection lines 121a can be electrically connected to the pixel driving circuit PD. The plurality of 1-1 connection lines 121a can transmit the voltage output from the pixel driving circuit PD to the first electrode CE1 or the second electrode CE2.

For example, the third protective layer 114 can be disposed on the second protective layer 113b. The third protective layer 114 can be disposed across the display area AA and the non-display area NA. In the bending area BA, the third protective layer 114 can cover side surfaces of the second protective layer 113b and an upper surface of the first protective layer 113a. The third protective layer 114 can be formed of an organic insulating material. For example, the third protective layer 114 can be formed of a photoresist, polyimide (PI), or photo acryl-based material, but the embodiments of the present disclosure are not limited thereto. For example, the first protective layer 113a, the second protective layer 113b, and the third protective layer 114 can be formed of the same material. The embodiments of the present disclosure are not limited thereto.

The plurality of 1-2 connection lines 121b can be disposed on the third protective layer 114. The plurality of 1-2 connection lines 121b can be connected or directly connected to the pixel driving circuit PD. For example, a part of the 1-2 connection line 121b can be directly connected to the pixel driving circuit PD through a contact hole of the third protective layer 114. The other part of the 1-2 connection line 121b can be electrically connected to the 1-1 connection line 121a through a contact hole of the third protective layer 114. However, the embodiments of the present disclosure are not limited thereto. The voltage output from the pixel driving circuit PD can be transmitted to the first electrode CE1 or the second electrode CE2 through the plurality of 1-2 connection lines 121b and other connection lines.

A first insulating layer 115a can be disposed on the plurality of 1-2 connection lines 121b. The first insulating layer 115a can be disposed across the display area AA and the non-display area NA, but the embodiments of the present disclosure are not limited thereto. The first insulating layer 115a can be formed of an organic insulation material, but the embodiments of the present disclosure are not limited thereto. For example, the first insulating layer 115a can be formed of a photoresist, polyimide (PI), or photo acryl-based material, but the embodiments of the present disclosure are not limited thereto.

The plurality of 1-3 connection lines 121c can be disposed on the first insulating layer 115a. The plurality of 1-3 connection lines 121c can be electrically connected to the plurality of 1-2 connection lines 121b. For example, the 1-3 connection line 121c can be electrically connected to the 1-2 connection line 121b through a contact hole of the first insulating layer 115a.

A second insulating layer 115b can be disposed on the plurality of the 1-3 connection lines 121c. The second insulating layer 115b can be disposed in the remaining area not including the bending area BA, but the embodiments of the present disclosure are not limited thereto. The second insulating layer 115b can be disposed in the display area AA, the first non-display area NA1, and the second non-display area NA2, but the embodiments of the present disclosure are not limited thereto. For example, a part of the second insulating layer 115b disposed in the bending area BA can be removed. The second insulating layer 115b can be formed of an organic insulation material, but the embodiments of the present disclosure are not limited thereto. For example, the second insulating layer 115b can be formed of a photoresist, polyimide (PI), or photo acryl-based material, but the embodiments of the present disclosure are not limited thereto.

A plurality of 1-4 connection lines 121d can be disposed on the second insulating layer 115b. The plurality of 1-4 connection lines 121d can be electrically connected to the plurality of 1-3 connection lines 121c. For example, the plurality of 1-4 connection lines 121d can be electrically connected to the 1-3 connection line 121c through contact holes of the second insulating layer 115b.

According to aspects of the present disclosure, a plurality of second connection lines 122 can be disposed on the second protective layer 113b in the non-display area NA. The plurality of second connection lines 122 can be lines for transmitting signals transmitted from the flexible circuit board (or the flexible film) 157 and the printed circuit board 160 (see FIG. 1) to the pad part PAD to the pixel driving circuit PD of the display area AA. For example, the plurality of second connection lines 122 can be electrically connected to the plurality of pad electrodes PE to receive signals from the flexible circuit board (or the flexible film) 157 and the printed circuit board.

For example, the plurality of second connection lines 122 can extend from the pad part PAD toward the display area AA to transmit signals to lines of the display area AA. In this case, the plurality of second connection lines 122 can serve as the link lines LL. The plurality of second connection lines 122 can include a 2-1 connection line 122a, a 2-2 connection line 122b, a 2-3 connection line 122c, and a 2-4 connection line 122d.

A plurality of 2-1 connection lines 122a can be disposed on the second protective layer 113b. The plurality of 2-1 connection lines 122a can extend from the second non-display area NA2 to the bending area BA and the first non-display area NA1. The plurality of 2-1 connection lines 122a can transmit the signals transmitted from the flexible circuit board (or the flexible film) 157 and the printed circuit board to the pad part PAD to the pixel driving circuit PD of the display area AA. For example, the 2-1 connection line 122a can be electrically connected to the pixel driving circuit PD through the first connection line 121 of the display area AA. In addition, the 2-1 connection line 122a can be electrically connected to the second electrode CE2 through the first connection line 121 and the contact electrode CCE of the display area AA. Accordingly, the cathode voltage can be transmitted from the pixel driving circuit PD to the light-emitting element ED through the second electrode CE2.

The plurality of 2-2 connection lines 122b can be disposed on the third protective layer 114. The plurality of 2-2 connection lines 122b can be disposed in the second non-display area NA2. The 2-2 connection line 122b can be electrically connected to the 2-1 connection line 122a through a contact hole of the third protective layer 114. Accordingly, the signals output from the flexible circuit board (or the flexible film) 157 and the printed circuit board can be transmitted to the 2-1 connection line 122a through the 2-2 connection line 122b.

The 2-3 connection line 122c can be disposed on the first insulating layer 115a. The 2-3 connection line 122c can be disposed in the second non-display area NA2. The 2-3 connection line 122c can be electrically connected to the 2-2 connection line 122b through a contact hole of the first insulating layer 115a. Accordingly, the signals output from the flexible circuit board (or the flexible film) 157 and the printed circuit board can be transmitted to the 2-1 connection line 122a through the 2-3 connection line 122c and the 2-2 connection line 122b.

The 2-4 connection line 122d can be disposed on the second insulating layer 115b. The 2-4 connection line 122d can be disposed in the second non-display area NA2. The 2-4 connection line 122d can be electrically connected to the 2-3 connection line 122c through a contact hole of the second insulating layer 115b. Accordingly, the signals output from the flexible film 157 and the printed circuit board can be transmitted to the 2-1 connection line 122a through the 2-4 connection line 122d, the 2-3 connection line 122c, and the 2-2 connection line 122b.

The plurality of first connection lines 121 and the plurality of second connection lines 122 can be formed of an excellent flexible conductive material or one of various conductive materials used in the display area AA. For example, the second connection line 122 of which a part is disposed in the bending area BA can be formed of an excellent flexible conductive material, such as gold (Au), silver (Ag), aluminum (Al), etc., but the embodiments of the present disclosure are not limited thereto. As another example, the plurality of first connection lines 121 and the plurality of second connection lines 122 can be formed of molybdenum (Mo), chromium (Cr), titanium (Ti), nickel (Ni), neodymium (Nd), copper (Cu), and an alloy of silver (Ag) and magnesium (Mg), or an alloy thereof, but the embodiments of the present disclosure are not limited thereto.

The third insulating layer 115c can be disposed on the plurality of first connection lines 121 and the plurality of second connection lines 122. The third insulating layer 115c can be disposed in the remaining area not including the bending area BA, but the embodiments of the present disclosure are not limited thereto. The third insulating layer 115c can be disposed in the display area AA, the first non-display area NA1, and the second non-display area NA2. A part of the third insulating layer 115c in the bending area BA can be removed. The third insulating layer 115c can be formed of an organic insulation material, but the embodiments of the present disclosure are not limited thereto. For example, the third insulating layer 115c can be formed of a photoresist, polyimide (PI), or photo acryl-based material, but the embodiments of the present disclosure are not limited thereto.

A plurality of banks BNK can be disposed on the third insulating layer 115c in the display area AA. The plurality of banks BNK can be disposed to overlap the plurality of sub-pixels, respectively. One or more light-emitting elements ED of the same type can be disposed on each of the plurality of banks BNK.

The plurality of signal lines TL can be disposed on the third insulating layer 115c in the display area AA. The plurality of signal lines TL can be disposed in an area between the plurality of banks BNK. For example, the plurality of signal lines TL can be disposed adjacent to one of the plurality of banks BNK.

The plurality of contact electrodes CCE can be disposed on the third insulating layer 115c in the display area AA. The plurality of contact electrodes CCE can supply the cathode voltage from the pixel driving circuit PD to the second electrode CE2.

The first electrode CE1 can be disposed on the bank BNK. For example, the first electrode CE1 can be disposed to extend from an adjacent signal line TL toward an upper portion of the bank BNK. The first electrode CE1 can be disposed on an upper surface of the bank BNK and side surfaces of the bank BNK. For example, the first electrode CE1 can be disposed to extend from the signal line TL on the upper surface of the third insulating layer 115c to the side surfaces of the bank BNK and the upper surface of the bank BNK.

Referring to FIG. 9, the first electrode CE1 can be formed of a plurality of conductive layers. For example, the first electrode CE1 can include a first conductive layer CE1a, a second conductive layer CE1b, a third conductive layer CE1c, and a fourth conductive layer CE1d, but the embodiments of the present disclosure are not limited thereto.

The first conductive layer CE1a can be disposed on the bank BNK. The second conductive layer CE1b can be disposed on the first conductive layer CE1a. The third conductive layer CE1c can be disposed on the second conductive layer CE1b, and the fourth conductive layer CE1d can be disposed on the third conductive layer CE1c. For example, each of the first conductive layer CE1a, the second conductive layer CEb, the third conductive layer CE1c, and the fourth conductive layer CE1d can be formed of titanium (Ti), molybdenum (Mo), aluminum (Al), or titanium (Ti) and indium tin oxide (ITO), but the embodiments of the present disclosure are not limited thereto.

According to aspects of the present disclosure, among the plurality of conductive layers forming the first electrode CE1, some of the conductive layers, which have good reflection efficiency, can be formed as an alignment key for aligning the light-emitting element ED and/or a reflector. For example, the second conductive layer CE1b among the plurality of conductive layers of the first electrode CE1 can include a reflective material. For example, the second conductive layer CE1b can include aluminum (Al), but the embodiments of the present disclosure are not limited thereto. Accordingly, the second conductive layer CE1b can be formed as a reflector. In addition, due to the high reflection efficiency of the second conductive layer CE1b, the second conductive layer CE1b can be easily identified in the manufacturing process, and thus the location or transfer location of the light-emitting element ED can be aligned based on the second conductive layer CE1b.

For example, to form the second conductive layer CE1b as a reflector, parts of the third conductive layer CE1c and the fourth conductive layer CE1d that cover the second conductive layer CE1b can be removed or etched. For example, parts of the third conductive layer CE1c and the fourth conductive layer CE1d that are disposed on the bank BNK can be removed or etched to expose an upper surface of the second conductive layer CE1b. For example, central portions and border portions (or edge portions) of the third conductive layer CE1c and the fourth conductive layer CE1d, in which a solder pattern SDP is disposed can be left, and the remaining portions not including the central and border portions can be removed. For example, the border portion (or the edge portion) of each of the third conductive layer CE1c formed of titanium (Ti) and the fourth conductive layer CE1d formed of indium tin oxide (ITO) may not be etched. Accordingly, it is possible to prevent other conductive layers of the first electrode CE1 from being corroded by a tetramethylammonium hydroxide (TMAH) solution used in a mask process of the first electrode CE1.

According to aspects of the present disclosure, the first conductive layer CE1a and the third conductive layer CE1c can include titanium (Ti) or molybdenum (Mo). The second conductive layer CE1b can include aluminum (Al). The fourth conductive layer CE1d can include a transparent conductive oxide layer, such as indium tin oxide (ITO) or indium zinc oxide (IZO), which has high adhesion to the solder pattern SDP, corrosion resistance, and acid resistance. However, the embodiments of the present disclosure are not limited thereto.

The first conductive layer CE1a, the second conductive layer CE1b, the third conductive layer CE1c, and the fourth conductive layer CE1d can be sequentially deposited and then patterned by performing a photolithography process and an etching process, but the embodiments of the present disclosure are not limited thereto.

According to aspects of the present disclosure, the signal line TL, the contact electrode CCE, and the pad electrode PE that are disposed on the same layer as the first electrode CE1 can be formed in multiple conductive layers, but the embodiments of the present disclosure are not limited thereto. For example, the signal line TL, the contact electrode CCE, and the pad electrode PE can be formed in multiple layers of indium tin oxide (ITO)/titanium (Ti)/aluminum (Al)/titanium (Ti), but the embodiments of the present disclosure are not limited thereto.

According to aspects of the present disclosure, the solder pattern SDP can be disposed on the first electrode CE1 in each of the plurality of sub-pixels. The solder pattern SDP can bond the light-emitting element ED to the first electrode CE1. The first electrode CE1 and the light-emitting element ED can be electrically connected through eutectic bonding using the solder pattern SDP, but the embodiments of the present disclosure are not limited thereto. For example, when the solder pattern SDP is formed of indium (In) and the anode electrode 134 of the light-emitting element ED is formed of gold (Au), the solder pattern SDP and the anode electrode 134 can be bonded by applying heat and pressure during the transfer process of the light-emitting element ED. The light-emitting element ED can be bonded to the solder pattern SDP and the first electrode CE1 without a separate adhesive through eutectic bonding. For example, the solder pattern SDP can be formed of indium (In), tin (Sn), or an alloy thereof, but the embodiments of the present disclosure are not limited thereto. For example, the solder pattern SDP can be a bonding pad, etc., but the embodiments of the present disclosure are not limited thereto.

According to aspects of the present disclosure, a passivation layer 116 can be disposed on the plurality of signal lines TL, the plurality of first electrodes CE1, the plurality of contact electrodes CCE, and the third insulating layer 115c. For example, the passivation layer 116 can be disposed in the display area AA, the first non-display area NA1, and the second non-display area NA2. A part of the passivation layer 116, which is disposed in the bending area BA, can be removed. The part of the passivation layer 116 covering the plurality of pad electrodes PEs in the second non-display area NA2 can be removed. Since the passivation layer 116 is disposed to cover the remaining area not including the bending area BA and the area in which the plurality of pad electrodes PE and the solder pattern SDP are disposed, it is possible to reduce the penetration of moisture or impurities into the light-emitting element ED. For example, the passivation layer 116 can be formed of a single layer or multiple layers of silicon oxide (SiOₓ) or silicon nitride (SiNₓ), but the embodiments of the present disclosure are not limited thereto. For example, the passivation layer 116 can be a protective layer, an insulating layer, etc., but the embodiments of the present disclosure are not limited thereto. For example, the passivation layer 116 can include a hole exposing the solder pattern SDP.

The light-emitting element ED can be disposed on the solder pattern SDP in each of the plurality of sub-pixels. The first light-emitting element 130 can be disposed in the first sub-pixel SP1. The second light-emitting element 140 can be disposed in the second sub-pixel SP2. The third light-emitting element 150 can be disposed in the third sub-pixel SP3.

The light-emitting element ED can be formed on a silicon wafer by a method of metal organic chemical vapor deposition (MOCVD), CVD, plasma-enhanced CVD (PECVD), molecular beam epitaxy (MBE), hydride vapor phase epitaxy (HVPE), sputtering, etc., but the embodiments of the present disclosure are not limited thereto.

Referring to FIG. 9, the first light-emitting element 130 can include the anode electrode 134, a first semiconductor layer 131, an active layer 132, a second semiconductor layer 133, the cathode electrode 135, and an encapsulation film 136, but the embodiments of the present disclosure are not limited thereto. For example, the encapsulation film 136 may not be included in the first light-emitting element 130.

The first semiconductor layer 131 can be disposed on the solder pattern SDP. The second semiconductor layer 133 can be disposed on the first semiconductor layer 131.

For example, one of the first semiconductor layer 131 and the second semiconductor layer 133 can be formed of a compound semiconductor of group III-V, group II-VI, etc. and can be doped with an impurity (or a dopant). For example, one of the first semiconductor layer 131 and the second semiconductor layer 133 can be a semiconductor layer doped with an n-type impurity, and the other can be a semiconductor layer doped with a p-type impurity, but the embodiments of the present disclosure are not limited thereto. For example, at least one of the first semiconductor layer 131 and the second semiconductor layer 133 can be a layer formed of a material, such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), gallium arsenide (GaAs), etc., coated with an n-type or p-type impurity, but the embodiments of the present disclosure are not limited thereto. For example, the n-type impurity can be silicon (Si), germanium (Ge), selenium (Se), carbon (C), tellurium (Te), tin (Sn), etc., but the embodiments of the present disclosure are not limited thereto. For example, the p-type impurity can be magnesium (Mg), zinc (Zn), calcium (Ca), strontium (Sr), barium (Ba), beryllium (Be), or the like, but the embodiments of the present disclosure are not limited thereto.

For example, the first semiconductor layer 131 and the second semiconductor layer 133 can be a nitride semiconductor including an n-type impurity and a nitride semiconductor including a p-type impurity, respectively, but the embodiments of the present disclosure are not limited thereto. For example, the first semiconductor layer 131 can be a nitride semiconductor including a p-type impurity, and the second semiconductor layer 133 can be a nitride semiconductor including an n-type impurity, but the embodiments of the present disclosure are not limited thereto.

The active layer 132 can be disposed between the first semiconductor layer 131 and the second semiconductor layer 133. The active layer 132 can receive holes and electrons from the first semiconductor layer 131 and the second semiconductor layer 133 and emit light. For example, the active layer 132 can be formed in one of a single well structure, a multi-well structure, a single quantum well structure, a multi-quantum well (MQW) structure, a quantum dot structure, and a quantum wire structure, but the embodiments of the present disclosure are not limited thereto. For example, the active layer 132 can be formed of indium gallium nitride (InGaN), gallium nitride (GaN), etc., but the embodiments of the present disclosure are not limited thereto.

For another example, the active layer 132 can include a MQW structure having a well layer and a barrier layer having a greater band gap than the well layer. For example, the active layer 132 can have an InGaN layer as the well layer and an AlGaN layer as the barrier layer, but the embodiments of the present disclosure are not limited thereto.

The anode electrode 134 can be disposed between the first semiconductor layer 131 and the solder pattern SDP. For example, the anode electrode 134 can electrically connect the first semiconductor layer 131 to the first electrode CE1. The anode voltage output from the pixel driving circuit PD can be applied to the first semiconductor layer 131 through the signal line TL, the first electrode CE1, and the anode electrode 134. For example, the anode electrode 134 can be formed of a conductive material capable of eutectic bonding with the solder pattern SDP, but the embodiments of the present disclosure are not limited thereto. For example, the anode electrode 134 can be formed of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), an alloy thereof, etc., but the embodiments of the present disclosure are not limited thereto.

The cathode electrode 135 can be disposed on the second semiconductor layer 133. For example, the cathode electrode 135 can electrically connect the second semiconductor layer 133 to the second electrode CE2. The cathode voltage output from the pixel driving circuit PD can be applied to the second semiconductor layer 133 through the contact electrode CCE, the second electrode CE2, and the cathode electrode 135. The cathode electrode 135 can be formed of a transparent conductive material so that light emitted from the light-emitting element ED can emit upward with respect to the light-emitting element ED, but the embodiments of the present disclosure are not limited thereto. For example, the cathode electrode 135 can be formed of a material, such as indium tin oxide (ITO), indium zinc oxide (IZO), indium gallium zinc oxide (IGZO), etc., but the embodiments of the present disclosure are not limited thereto.

The encapsulation film 136 can be disposed on at least parts of the first semiconductor layer 131, the active layer 132, the second semiconductor layer 133, the anode electrode 134, and the cathode electrode 135. For example, the encapsulation film 136 can surround the at least parts of the first semiconductor layer 131, the active layer 132, the second semiconductor layer 133, the anode electrode 134, and the cathode electrode 135.

For example, the encapsulation film 136 can protect the first semiconductor layer 131, the active layer 132, and the second semiconductor layer 133. For example, the encapsulation film 136 can surround side surfaces of the first semiconductor layer 131, side surfaces of the active layer 132, and side surfaces of the second semiconductor layer 133.

For example, the encapsulation film 136 can be disposed on at least parts of the anode electrode 134 and the cathode electrode 135, for example, an edge portion (or border region or one side) of the anode electrode 134 and an edge portion (or border region or one side) of the cathode electrode 135. At least a part of the anode electrode 134 can be exposed with respect to the encapsulation film 136 to connect the anode electrode 134 to the solder pattern SDP. For example, at least a part of the cathode electrode 135 can be exposed with respect to the encapsulation film 136 to connect the cathode electrode 135 to the second electrode CE2. For example, the encapsulation film 136 can be formed of an insulating material, such as silicon nitride (SiNₓ) or silicon oxide (SiOₓ), but the embodiments of the present disclosure are not limited thereto.

As another example, the encapsulation film 136 can have a structure in which a reflective material is dispersed in a resin layer, but the embodiments of the present disclosure are not limited thereto. For example, the encapsulation film 136 can be manufactured to be a reflector having various structures, but the embodiments of the present disclosure are not limited thereto. Light emitted from the active layer 132 by the encapsulation film 136 can be reflected upward, thereby increasing light extraction efficiency. For example, the encapsulation film 136 can be a reflective layer, but the embodiments of the present disclosure are not limited thereto.

According to aspects of the present disclosure, the light-emitting element ED has been described as having a vertical structure, but the embodiments of the present disclosure are not limited thereto. For example, the light-emitting element ED can have a lateral structure or a flip chip structure.

The first light-emitting element 130 has been described with reference to FIG. 9, but the second light-emitting element 140 and the third light-emitting element 150 can have substantially the same structure as the first light-emitting element 130. For example, the second light-emitting element 140 and the third light-emitting element 150 can have substantially the same structure as the first semiconductor layer 131, the active layer 132, the second semiconductor layer 133, the anode electrode 134, the cathode electrode 135, and the encapsulation film 136 of the first light-emitting element 130.

Referring to FIGS. 8, 9, 15, and 16 together, in the embodiment of the present disclosure, the optical layer 117-1 can be disposed to surround the plurality of light-emitting elements ED in the display area AA. For example, the optical layer 117-1 can be disposed to cover the plurality of light-emitting elements ED and banks BNK in areas of the plurality of sub-pixels. For example, the optical layer 117-1 can cover the bank BNK, the passivation layer 116, and the plurality of light-emitting elements ED. The optical layer 117-1 can be disposed between the plurality of light-emitting elements ED and between the plurality of banks BNK or cover the plurality of light-emitting element ED and the plurality of banks BNK. For example, the optical layer 117-1 can be arranged on the entire surface of the display area AA. For example, the optical layer 117-1 can be disposed to surround the side portions of the light-emitting element ED and the bank BNK between the passivation layer 116 and the second electrode CE2, but the embodiments of the present disclosure are not limited thereto. For example, the optical layer 117-1 can be a first optical layer, a sidewall diffusion layer, etc., but the embodiments of the present disclosure are not limited thereto.

The optical layer 117-1 can include an organic insulation material having fine particles dispersed therein, but the embodiments of the present disclosure are not limited thereto. For example, the optical layer 117-1 can be formed of siloxane having fine metal particles, such as titanium dioxide (TiO₂) particles, dispersed therein, but the embodiments of the present disclosure are not limited thereto. Light emitted from the plurality of light-emitting elements ED can be scattered by the fine particles dispersed in the optical layer 117-1 and emitted to the outside of the display apparatus 1000. Accordingly, the optical layer 117-1 can increase the extraction efficiency of the light emitted from the plurality of light-emitting elements ED.

Referring to FIGS. 8 and 16 together, the second electrode CE2 can be disposed on the optical layer 117-1. For example, the second electrode CE2 can be electrically connected to the plurality of contact electrodes CCE through contact holes 117H of the optical layer 117-1. For example, the second electrode CE2 can be disposed on the plurality of light-emitting elements ED. For example, the second electrode CE2 can include a transparent conductive oxide, such as indium tin oxide (ITO), indium zinc oxide (IZO), etc., but the embodiments of the present disclosure are not limited thereto. For example, the second electrode CE2 can be disposed in contact with the cathode electrode 135 (see FIG. 9). For example, the second electrode CE2 can overlap the optical layer 117-1. For example, the second electrode CE2 can cover a flat outer surface of the optical layer 117-1.

The second electrode CE2 can extend continuously in the first direction of the substrate 110. The first direction can be the row direction. Accordingly, the second electrode CE2 can be connected in common to the plurality of pixels PX disposed in the same row direction, which is the first direction of the substrate 110.

For example, the second electrode CE2 can include a first line CE2-1 connected to pixels PX of the n^{th} row and a second line CE2-2 connected to pixels PX of the (n+1)^{th} row. The first line CE2-1 and the second line CE2-2 can be disposed to be spaced apart from each other. For example, the first line CE2-1 and the second line CE2-2 of the second electrode CE2 can be arranged to be spaced apart from each other in the second direction of the substrate 110. The second direction can be the column direction. Accordingly, each of the plurality of sub-pixels disposed in the same column direction can be connected to the first line CE2-1 or the second line CE2-2 of the different second electrodes CE2.

An upper optical layer 117-2 can be disposed on the second electrode CE2. The upper optical layer 117-2 can be disposed to overlap the plurality of light-emitting elements ED and the optical layer 117-1. Since the upper optical layer 117-2 is disposed above the second electrode CE2 and the plurality of light-emitting elements ED, it is possible to eliminate spots (mura) that can occur in some of the plurality of light-emitting elements ED. For example, when the plurality of light-emitting elements ED are transferred onto the substrate 110 of the display apparatus 1000, an area of which distances between the plurality of light-emitting elements ED are not uniform can occur due to a process deviation, etc. When the distances between the plurality of light-emitting elements ED are not uniform, a light-emitting area of each of the plurality of light-emitting elements ED can be disposed non-uniformly, thereby making spots (mura) visible to a user. Accordingly, since the upper optical layer 117-2 to uniformly diffuse light above the plurality of light-emitting elements ED is formed, it is possible to prevent the light emitted from some light-emitting elements ED from being visible as spots. Accordingly, since the light emitted from the plurality of light-emitting elements ED is uniformly diffused by the upper optical layer 117-2 and extracted to the outside of the display apparatus 1000, it is possible to improve the luminance uniformity of the display apparatus 1000.

The upper optical layer 117-2 can be formed of an organic insulation material having fine particles dispersed therein, but the embodiments of the present disclosure are not limited thereto. For example, the upper optical layer 117-2 can be formed of siloxane having fine metal particles, such as titanium dioxide (TiO₂) particles, dispersed therein, but the embodiments of the present disclosure are not limited thereto. For example, the upper optical layer 117-2 can be formed of the same material as the optical layer 117-1, but the embodiments of the present disclosure are not limited thereto. For example, the upper optical layer 117-2 can be a diffusion layer, an upper diffusion layer, etc., but the embodiments of the present disclosure are not limited thereto.

A refractive index of the upper optical layer 117-2 can range from 1.50 to 1.55. In one example, the refractive index of the upper optical layer 117-2 can be 1.53.

According to aspects of the present disclosure, the light emitted from the plurality of light-emitting elements ED can be scattered by fine particles dispersed in the upper optical layer 117-2 and emitted to the outside of the display apparatus 1000. The upper optical layer 117-2 can uniformly mix the light emitted from the plurality of light-emitting elements ED, thereby further improving the luminance uniformity of the display apparatus 1000. In addition, it is possible to increase the light extraction efficiency of the display apparatus 1000 by the light scattered from the fine particles, thereby enabling the low-power driving of the display apparatus 1000.

A black matrix BM can be disposed on the second electrode CE2, the optical layer 117-1, and the upper optical layer 117-2 in the display area AA. For example, the black matrix BM can fill the contact hole 117H of the optical layer 117-1. Since the black matrix BM is formed to cover the display area AA, it is possible to reduce color mixing of light of a plurality of sub-pixels and external light reflection. For example, since the black matrix BM is also disposed in the contact hole 117H by which the second electrode CE2 and the contact electrode CCE are connected, it is possible to prevent light leakage between neighboring sub-pixels.

For example, the black matrix BM can be formed of an opaque material, but the embodiments of the present disclosure are not limited thereto. For example, the black matrix BM can be an organic insulation material to which a black pigment or black dye is added, but the embodiments of the present disclosure are not limited thereto.

A cover layer 118 can be disposed on the black matrix BM in the display area AA. The cover layer 118 can protect components under the cover layer 118. For example, the cover layer 118 can be formed of an organic insulation material, but the embodiments of the present disclosure are not limited thereto. For example, the cover layer 118 can be formed of a photoresist, polyimide (PI), or photo acryl-based material, but the embodiments of the present disclosure are not limited thereto. For example, the cover layer 118 can be an overcoating layer, an insulating layer, etc., but the embodiments of the present disclosure are not limited thereto.

The polarizing layer 293 can be disposed on the cover layer 118 via a first adhesive layer 291. The cover member 155 can be disposed on the polarizing layer 293 via a second adhesive layer 295. For example, the first adhesive layer 291 and the second adhesive layer 295 can include an OCA, an OCR, a PSA, etc., but the embodiments of the present disclosure are not limited thereto.

According to aspects of the present disclosure, the plurality of pad electrodes PEs can be disposed on the third insulating layer 115c in the second non-display area NA2. For example, at least parts of the plurality of pad electrodes PE can be exposed with respect to the passivation layer 116. For example, the plurality of pad electrodes PE can be electrically connected to the 2-4 connection line 122d through a contact hole of the third insulating layer 115c.

An adhesive layer ACF can be disposed on the plurality of pad electrodes PE. The adhesive layer ACF can be an adhesive layer in which conductive balls are dispersed in an insulation material, but the embodiments of the present disclosure are not limited thereto. When heat or pressure is applied to the adhesive layer ACF, the conductive balls can be electrically connected at a portion in which the heat or pressure is applied, thereby providing conductive characteristics. The adhesive layer ACF can be disposed between the plurality of pad electrodes PE and the flexible circuit board (or the flexible film) 157 to attach or bond the flexible circuit board (or the flexible film) 157 to the plurality of pad electrodes PE. For example, the adhesive layer ACF can be an anisotropic conductive film (ACF), but the embodiments of the present disclosure are not limited thereto.

The flexible circuit board (or the flexible film) 157 can be disposed on the adhesive layer ACF. The flexible circuit board (or the flexible film) 157 can be electrically connected to the plurality of pad electrodes PE through the adhesive layer ACF. Accordingly, signals output from the flexible circuit board (or the flexible film) 157 and the printed circuit board can be transmitted to the pixel driving circuit PD of the display area AA through the plurality of pad electrodes PE, the 2-4 connection line 122d, the 2-3 connection line 122c, the 2-2 connection line 122b, and the 2-1 connection line 122a.

FIGS. 10 to 13 are views illustrating an apparatus to which the display apparatus according to the embodiments of the present disclosure is applied.

Referring to FIGS. 10 to 13, the display apparatus 1000 according to embodiments of the present disclosure can be included in various devices or electronic devices. For example, referring to FIGS. 10 to 13, various electronic devices can include a wearable device 1100, a mobile device 1200, a notebook PC 1300, and a monitor or TV 1400, but the embodiments of the present disclosure are not limited thereto.

The wearable device 1100, the mobile device 1200, the notebook PC 1300, and the monitor or TV 1400 can include case units 1005, 1010, 1015, and 1020, respectively, and the display panel 100 and the display apparatus 1000 according to the embodiments of the present disclosure, which are described in FIGS. 1 to 9.

For example, the display apparatus according to the embodiment of the present disclosure can be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an e-book, a portable multimedia player (PMP), a personal digital assistant (PDA), an MP3 player, a mobile medical device, a desktop PC, a laptop PC, a netbook computer, a workstation, a navigation system, a vehicle display device, a theater display device, a television, a wallpaper device, a signage device, a game device, a laptop computer, a monitor, a camera, a camcorder, a home appliances, etc.

FIG. 14 is a plan view illustrating an area in which one of a plurality of pixel driving circuits is disposed.

Referring to FIGS. 3, 5, and 14 together, one pixel driving circuit PD can be electrically connected to the plurality of signal lines TL electrically connected to the plurality of sub-pixels. The plurality of sub-pixels can include the plurality of light-emitting elements ED (see FIG. 3) disposed in the same column direction SP1, SP2, SP3, . . . , and SP16 and the same row direction Row1, Row2, Row3, . . . , and Row16.

The plurality of signal lines TL extending in the column direction can be disposed between the plurality of sub-pixels. The plurality of signal lines TL can include a first line AND_P and a second line AND_R. The first line AND_P and the second line AND_R can be disposed to be spaced apart from each other in the first direction X, for example, the row direction. The first line AND_P and the second line AND_R can be electrically connected to each of the pair of sub-pixels. The light-emitting element ED can be disposed in each of the pair of sub-pixels. One of the light-emitting elements ED can be a main light-emitting element, and the other can be a redundancy light-emitting element. For example, referring to FIG. 5, the 1-1 light-emitting element 130a, the 2-1 light-emitting element 140a, and the 3-1 light-emitting element 150a transferred onto one pixel PX can be main light-emitting elements ED. In addition, the 1-2 light-emitting element 130b, the 2-2 light-emitting element 140b, and the 3-2 light-emitting element 150b can be redundancy light-emitting elements ED.

The first line AND_P can be a signal line disposed in an odd column. For example, referring to FIGS. 5 and 14 together, the first line AND_P can be the first signal line TL1, the third signal line TL3, and the fifth signal line TL5. The second line AND_R can be a signal line disposed in an even column. For example, the second line AND_R can be the second signal line TL2, the fourth signal line TLA, and the sixth signal line TL6. The first line AND_P and the second line AND_R can be referred to as signal lines.

The plurality of second electrodes CE2 can be disposed to extend in the row direction. Each of the plurality of second electrodes CE2 can be disposed to be spaced apart from each other in the second direction Y, for example, the column direction.

The plurality of signal lines TL connected to at least one pixel driving circuit PD can be radially connected to connect a first sub-pixel SP1 disposed at a first location of a first row Row1 to a sixteenth sub-pixel SP16 disposed opposite to the first sub-pixel SP1 and at a sixteenth location of the first row Row1 to the pixel driving circuit PD. For example, the shape in which the plurality of signal lines TL are connected can be a rhombus shape or a shape of a letter “I” in a plan view.

Referring to FIG. 17, the optical layer 117-1 according to one embodiment of the present disclosure can be disposed on the entire surface of the active area in which the light-emitting element is disposed. For example, the light-emitting element can refer to the second light-emitting element 140. The second light-emitting element 140 can be disposed so that an n^{th} second light-emitting element 140n and an (n+1)^{th} second light-emitting element 140n+1 are spaced apart from each other in the same column direction. The n^{th} second light-emitting element 140n can include the 2-1 light-emitting element 140a that is the main light-emitting element and the 2-2 light-emitting element 140b that is the redundancy light-emitting element, which are disposed on the bank BNK. In addition, the (n+1)^{th} second light-emitting element 140 (n+1) can include the 2-1 light-emitting element 140a that is the main light-emitting element and the 2-2 light-emitting element 140b that is the redundancy light-emitting element, which are disposed on the bank BNK.

The second electrode CE2 can be electrically connected to the contact electrode CCE through the contact hole 117H disposed on the optical layer 117-1 to transmit a voltage output from the pixel driving circuit PD to the light-emitting element 140. The contact hole 117H can be formed by performing an exposure process and a development process on the optical layer 117-1. However, it is difficult to form the microscopic contact hole 117H in the optical layer 117-1.

For example, the optical layer 117-1 can include an organic insulation material having fine metal particles dispersed therein. The organic insulation material can include a photoactive compound (PAC) and a polymer. For example, the photoactive compound (PAC) can include diazoquinone. For example, the polymer can include a novolac resin, but is not limited thereto.

When the organic insulation material is exposed to light during the exposure process, the solubility of the polymer increases in an area exposed to light to be easily decomposed in a developer, thereby patterning a contact hole, etc. However, the fine particles dispersed in the optical layer 117-1 disperse light supplied during the exposure process. Then, the amount of exposure required for dissolution can be reduced, thereby preventing the polymer from being decomposed. Accordingly, it is difficult to form the microscopic contact hole 117H, and a pattern defect can occur. For example, the optical layer 117-1 in the contact hole 117H is not completely removed, and a residual film 117r can remain. Alternatively, as illustrated in area “A”, since the amount of exposure can decrease, the contact hole 117H is not completely formed, thereby causing a defect in which the contact electrode CCE is not exposed.

When the second electrode CE2 is disposed in the contact hole 117H in which the residual film 117r remains, a contact defect can occur between the contact electrode CCE and the second electrode CE2 due to the residual film 117r. Accordingly, a voltage is not transmitted from the pixel driving circuit PD to the light-emitting element 140, thereby causing a defective pixel, such as a dark spot, etc.

Accordingly, in another embodiment of the present disclosure, it is possible to prevent the residual film from remaining in the contact hole 117H or prevent the contact electrode CCE from not being exposed, thereby preventing the occurrence of a defective pixel.

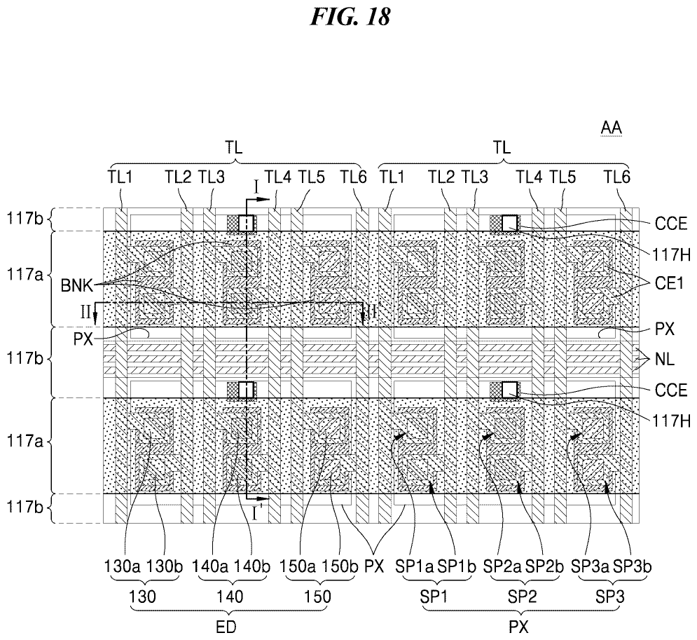

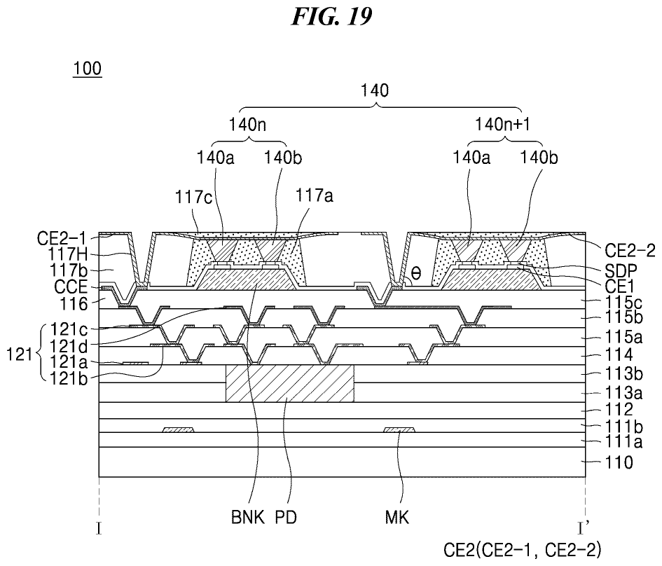

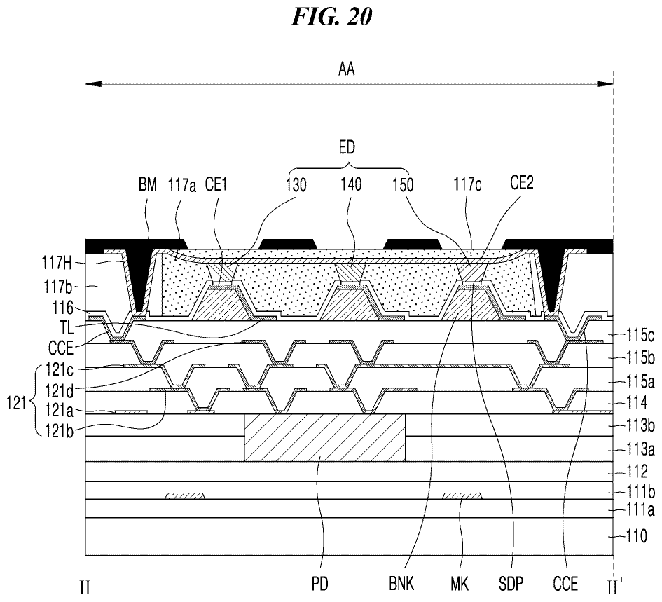

FIG. 18 is a plan view of the display apparatus according to another embodiment of the present disclosure. FIG. 19 is a cross-sectional view along line I-I′ in FIG. 18. In addition, FIG. 20 is a cross-sectional view along line II-II′ in FIG. 18. In FIG. 19, for convenience of description, the black matrix BM, the cover layer 118, the first adhesive layer 291, the polarizing layer 293, the second adhesive layer 295, and the cover member 155 are omitted.

In FIGS. 18 to 20, the same components as those described in FIGS. 8 and 9 are denoted as the same reference numerals, and the descriptions thereof are simplified or omitted. In addition, in the embodiment of the present disclosure, the second sub-pixel SP2 is described for convenience of description, but the configuration of the first sub-pixel SP1 and the third sub-pixel SP3 can have substantially the same structure as the configuration of the second sub-pixel SP2.

Referring to FIGS. 18 to 20, a first optical layer 117a can be disposed on the display area AA. The first optical layers 117a can extend in the first direction and can be disposed to be spaced apart from each other in the second direction. For example, the first direction can be the row direction and the second direction can be the column direction, but the embodiments of the present disclosure are not limited thereto. The first optical layer 117a can be disposed in a line shape continuously extending in the first direction.

The first optical layer 117a can be disposed to surround the plurality of light-emitting elements ED. For example, the first optical layer 117a can cover the plurality of light-emitting elements ED and banks BNK in the plurality of pixels PX. For example, the plurality of pixels PX disposed along the same row, for example, in the first direction, can share one first optical layer 117a. In addition, different first optical layers 117a can be disposed in the plurality of pixels PX disposed along the same column, for example, in the second direction.

For example, referring to FIGS. 18 and 19, the second light-emitting element 140 can be disposed so that the n^{th} second light-emitting element 140n and the (n+1)^{th} second light-emitting element 140 (n+1) are spaced apart from each other in the same column direction. The n^{th} second light-emitting element 140n can include the 2-1 light-emitting element 140a that is the main light-emitting element and the 2-2 light-emitting element 140b that is the redundancy light-emitting element, which are disposed on the bank BNK. In addition, the (n+1)^{th} second light-emitting element 140 (n+1) can include the 2-1 light-emitting element 140a that is the main light-emitting element and the 2-2 light-emitting element 140b that is the redundancy light-emitting element, which are disposed on the bank BNK.

For example, the n^{th} second light-emitting element 140n and the (n+1)^{th} second light-emitting element 140 (n+1) disposed along the same row, for example, in the second direction, can be surrounded by different first optical layers 117a.

The first optical layer 117a can cover a part of the passivation layer 116, the bank BNK, and a space between the plurality of light-emitting elements ED. The first optical layer 117a can be disposed to surround the side portions of the plurality of light-emitting elements ED. The first optical layer 117a can have a thickness of the same level as an upper surface of each of the plurality of light-emitting elements ED.

The first optical layer 117a can include an organic insulation material having fine particles dispersed therein. For example, the first optical layer 117a can be formed of siloxane having fine metal particles, such as titanium dioxide (Ti (2) particles, dispersed therein. Light from the plurality of light-emitting elements ED can be scattered by the fine particles dispersed in the first optical layer 117a and emitted to the outside of the display apparatus 1000. Accordingly, the first optical layer 117a can increase the extraction efficiency of the light emitted from the plurality of light-emitting elements ED. For example, the first optical layer 117a can be a diffusion layer, a sidewall diffusion layer, etc., but the embodiments of the present disclosure are not limited thereto.

The second optical layer 117b can be disposed on the passivation layer 116 in the display area AA. For example, the second optical layer 117b can be disposed to surround the first optical layer 117a. The second optical layer 117b can come into contact with side surfaces of the first optical layer 117a.

The second optical layer 117b can be disposed between the first optical layers 117a disposed to be spaced apart from each other in the second direction. For example, the second optical layer 117b can be disposed in the areas between the plurality of pixels PX disposed along the same column, for example, in the second direction. For example, the second optical layer 117b can be disposed along the same row, for example, in the first direction. The second optical layer 117b can be disposed to vertically overlap the plurality of communication lines NL. For example, the second optical layer 117b can be a diffusion layer, a diffusion layer window, a window diffusion layer, etc., but the embodiments of the present disclosure are not limited thereto.

The second optical layer 117b can be formed of an organic insulation material. The second optical layer 117b can include the same organic insulation material as the first optical layer 117a. For example, the first optical layer 117a can include fine particles, and the second optical layer 117b may not include fine particles. Accordingly, the second optical layer 117b can be a single component of an organic insulation material. For example, the second optical layer 117b can be formed of siloxane, but is not limited to such a material.

The second optical layer 117b can include the contact hole 117H. The contact hole 117H of the second optical layer 117b can expose a part of a surface of the contact electrode CCE.

The contact hole 117H in the second optical layer 117b can have a width that increases from an upper portion to a lower portion, which expose the contact electrode CCE. Accordingly, a sidewall of the contact hole 117H can be an inclined surface having inclination. An inclination angle θ of the sidewall of the contact hole 117H can have an inclination angle θ that does not exceed 90 degrees with respect to a bottom surface of the second optical layer 117b disposed outside the contact hole 117H.

According to aspects of the present disclosure, since the second optical layer 117b is an organic insulation material not including fine particles, the amount of exposure required for dissolving the organic insulation material can be sufficiently supplied during the exposure process. Accordingly, it is possible to prevent the occurrence of a defect in which the residual film is formed in the contact hole 117H or the contact electrode CCE is not exposed. Accordingly, it is possible to prevent the occurrence of a defective pixel, thereby improving the reliability of a product.

A thickness of the first optical layer 117a can be smaller than a thickness of the second optical layer 117b. For example, a maximum thickness of the first optical layer 117a can be smaller than a maximum thickness of the second optical layer 117b. Accordingly, in a plan view, the area in which the first optical layer 117a is disposed can include a concave portion that is recessed inward more than an upper surface of the second optical layer 117b.

The second electrode CE2 can be disposed on the first optical layer 117a and the second optical layer 117b. The second electrode CE2 can be electrically connected to the plurality of contact electrodes CCE through the contact hole 117H of the second optical layer 117b. The second electrode CE2 can be further electrically connected to the pixel driving circuit PD below the plurality of light-emitting elements ED. The second electrode CE2 can be disposed to come into contact with the cathode electrode 135 (see FIG. 9) of each of the plurality of light-emitting elements ED. The second electrode CE2 can cover the upper surface of the first optical layer 117a and extend toward the second optical layer 117b. Accordingly, a part of the second electrode CE2 can overlap the second optical layer 117b.

The inclination angle θ of the sidewall of the contact hole 117H disposed on the second optical layer 117b may not exceed 90 degrees with respect to the bottom surface of the second optical layer 117b disposed outside the contact hole 117H. For example, the second electrode CE2 can be disposed along the shape of the sidewall and bottom surface of the contact hole 117H. When the sidewall of the contact hole 117H has an inclination angle greater than 90 degrees with respect to the bottom surface of the second optical layer 117b, a defect in which the second electrode CE2 is disconnected can occur. Accordingly, it is preferable that the inclination angle of the sidewall of the contact hole 117H does not exceed 90 degrees.

The second electrode CE2 can continuously extend above the first optical layer 117a, the second optical layer 117b, and the light-emitting element ED. The area in which the first optical layer 117a is disposed can include the concave portion recessed inward of the upper surface of the second optical layer 117b. Accordingly, a first portion of the second electrode CE2 disposed on the first optical layer 117a can be disposed along the concave portion, and thus can be disposed at a lower location than a second portion of the second electrode CE2 disposed on the second optical layer 117b.

A third optical layer 117c can be disposed on the second electrode CE2. The third optical layer 117c can be disposed to overlap the plurality of light-emitting elements ED and the first optical layer 117a. The third optical layer 117c can include an organic insulation material having fine particles dispersed therein. For example, the third optical layer 117c can be formed of the same material as the first optical layer 117a. The third optical layer 117c can be referred to as a diffusion layer, an upper diffusion layer, etc.

The third optical layer 117c can uniformly mix the light emitted from the plurality of light-emitting elements ED, thereby further improving the luminance uniformity of the display apparatus 1000. In addition, it is possible to increase the light extraction efficiency of the display apparatus 1000 by the light scattered from the fine particles dispersed in the third optical layer 117c. Accordingly, the display apparatus 1000 can be driven at low power.

Referring to FIG. 20, the black matrix BM can be disposed on the second electrode CE2, the first optical layer 117a, the second optical layer 117b, and the third optical layer 117c in the display area AA. For example, the black matrix BM can fill the contact hole 117H of the second optical layer 117b. The black matrix BM can prevent the mixing phenomenon of different colors of the plurality of sub-pixels and the light leakage phenomenon, and reduce external light reflection.

According to the embodiment of the present disclosure, the first optical layer 117a including an organic insulation material having fine metal particles dispersed therein and the second optical layer 117b including an organic insulation material not including fine metal particles can be disposed in a first area surrounding the light-emitting element ED. Accordingly, it is possible to prevent the occurrence of a defect in which the residual film is formed in the contact hole, which exposes the contact electrode during the exposure process, or the contact electrode is not exposed. Accordingly, it is possible to prevent the occurrence of a defective pixel, thereby improving the reliability of a product.

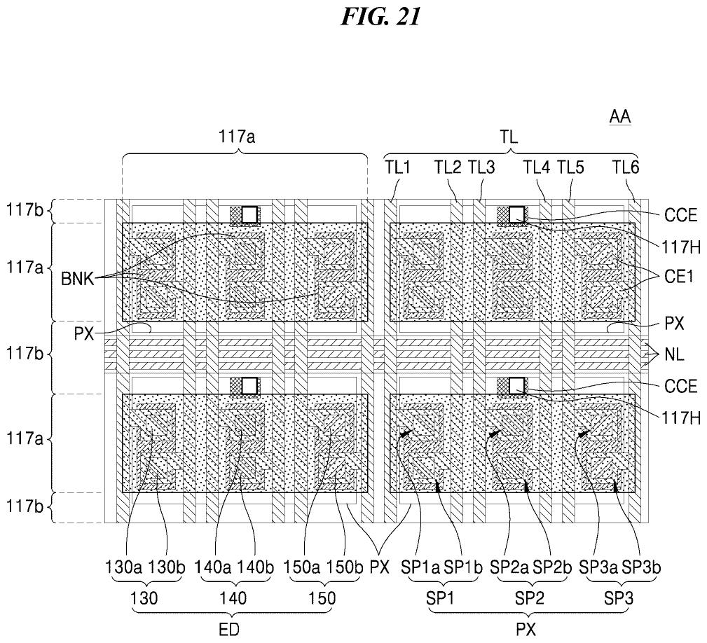

FIG. 21 is a plan view of a display apparatus according to still another embodiment of the present disclosure.

Particularly, FIG. 21 illustrates a shape in which the first optical layer 117a is arranged, which differs from another embodiment of the present disclosure according to FIG. 18, in a plan view. Accordingly, in FIG. 21, the same components as those described in FIGS. 18 to 20 are denoted as the same reference numerals, and the descriptions thereof are simplified or omitted.

Referring to FIG. 21, the first optical layer 117a can be disposed on the display area AA. The first optical layer 117a can be disposed along with some of the plurality of pixels PX. For example, one pixel PX can share one first optical layer 117a. Different first optical layers 117a can be disposed in the plurality of pixels PX disposed in the same row direction. Accordingly, the first optical layer 117a can be implemented in an island shape that is distinguished with respect to each pixel PX.

The second optical layer 117b can be disposed to surround the first optical layer 117a. For example, the second optical layer 117b can come into contact with four side surfaces of the first optical layer 117a implemented in an island shape. The second optical layer 117b can be disposed in areas between neighboring pixels PX in the row direction and the column direction.

The first optical layer 117a can be formed of an organic insulation material having fine metal particles dispersed therein, and the second optical layer 117b can be formed of an organic insulation material not including fine metal particles.

The second optical layer 117b can be disposed in areas between neighboring pixels PX in the same row direction. For example, the third light-emitting element 150 of one pixel PX can be disposed in the same row direction as the first light-emitting element 130 of the neighboring pixel PX, and the second optical layer 117b can be disposed between the two light-emitting elements 150 and 130.

Accordingly, it is possible to prevent color mixing between light emitted from the third light-emitting element 150 of one pixel PX in the same row direction and light emitted from the first light-emitting element 130 of the neighboring pixel PX.

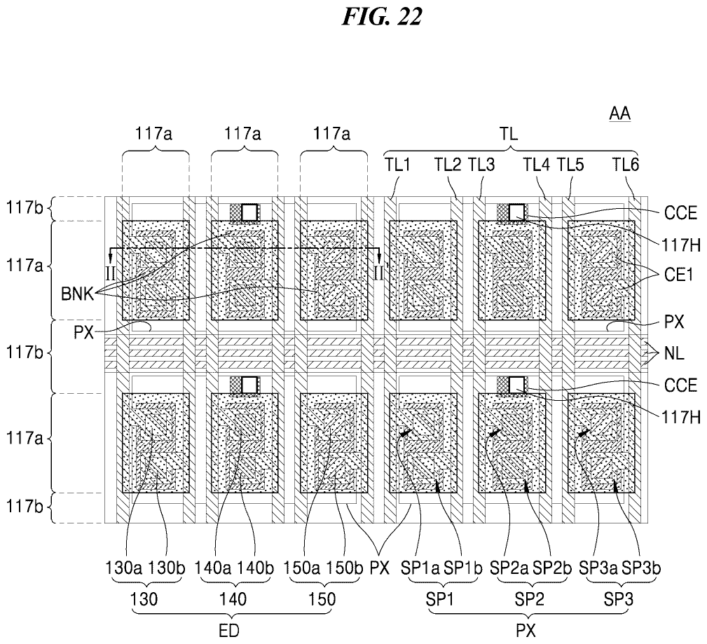

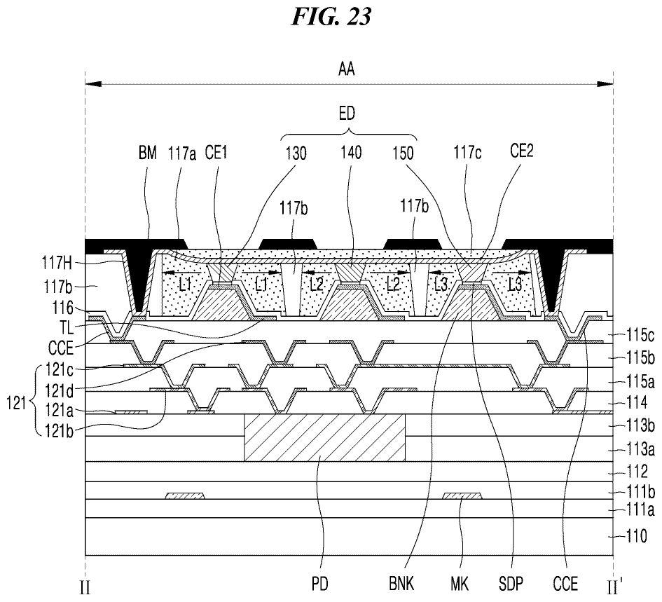

FIG. 22 is a plan view of a display apparatus according to yet another embodiment of the present disclosure. In addition, FIG. 23 is a cross-sectional view along line II-II′ in FIG. 22. In FIG. 22, the black matrix BM is omitted for convenience of description. In FIG. 23, for convenience of description, the cover layer 118, the first adhesive layer 291, the polarizing layer 293, the second adhesive layer 295, and the cover member 155 are omitted.

In FIGS. 22 and 23, the same components as those described in FIGS. 18 to 20 are denoted as the same reference numerals, and the descriptions thereof are simplified or omitted.

Referring to FIGS. 22 and 23, the first optical layer 117a can be disposed on the display area AA. The first optical layer 117a can be separately disposed in a plurality of pattern shapes on one pixel PX. For example, the first optical layer 117a can be disposed on each of the plurality of sub-pixels SP1, SP2, and SP3. For example, one first optical layer 117a can be disposed in one first sub-pixel SP1. One first optical layer 117a can be disposed in one second sub-pixel SP2. In addition, one first optical layer 117a can be disposed in one third sub-pixel SP3. Accordingly, the first optical layer 117a can have an island shape that is distinguished with respect to each sub-pixel SP1, SP2, or SP3.

The second optical layer 117b can be disposed to surround the first optical layer 117a. For example, the second optical layer 117b can come into contact with each surface of the first optical layer 117a implemented in an island shape.

The second optical layer 117b can be arranged in areas between neighboring sub-pixels SP1, SP2, and SP3 in the same row direction in one pixel PX. For example, the second optical layer 117b can be disposed in the areas between the first sub-pixel SP1, the second sub-pixel SP2, and the third sub-pixel SP3.

Accordingly, it is possible to prevent color mixing between the light-emitting elements ED disposed in one sub-pixel. For example, referring to FIG. 23, one sub-pixel can include the first light-emitting element 130, the second light-emitting element 140, and the third light-emitting element 150. The first light-emitting element 130 can emit light L1 of a first color, the second light-emitting element 140 can emit light L2 of a second color, and the third light-emitting element 150 can emit light L3 of a third color. The light L1 of the first color, the light L2 of the second color, and the light L3 of the third color can be light of different colors.

Since the second optical layer 117b is disposed in the area between the first light-emitting element 130 and the second light-emitting element 140, it is possible to prevent color mixing between the light L1 of the first color of the first light-emitting element 130 and the light L2 of the second color of the second light-emitting element 140. In addition, since the second optical layer 117b is disposed in the area between the second light-emitting element 140 and the third light-emitting element 150, it is possible to prevent color mixing between the light L2 of the second color of the second light-emitting element 140 and the light L3 of the third color of the third light-emitting element 150.

The second optical layer 117b can include the contact hole 117H that exposes a part of the surface of the contact electrode CCE. Since the second optical layer 117b is formed of an organic insulation material not including fine particles, it is possible to prevent a defect in which the residual film is formed in the contact hole 117H or the contact electrode CCE is not exposed. In addition, the contact hole 117H having the size of a fine line width can be formed. For example, the line width of the contact hole 117H can range from 6 μm to 8 μm.

The second electrode CE can be disposed on the first optical layer 117a and the second optical layer 117b. A part of the second electrode CE2 can be electrically connected to the plurality of contact electrodes CCE through the contact hole 117H of the second optical layer 117b, and the other part can be electrically connected to the light-emitting element ED.

The third optical layer 117c can be disposed on the second electrode CE2. The third optical layer 117c can include the same organic insulation material as the first optical layer 117a. For example, the third optical layer 117c can include an organic insulation material having fine metal particles dispersed therein.

The black matrix BM can be disposed on the second electrode CE2, the first optical layer 117a, the second optical layer 117b, and the third optical layer 117c in the display area AA. For example, the black matrix BM can fill the contact hole 117H of the second optical layer 117b. The black matrix BM can prevent the mixing phenomenon of different colors of the plurality of sub-pixels and the light leakage phenomenon, and reduce external light reflection.

The black matrix BM can include a plurality of openings. The opening of the black matrix BM can be disposed to correspond to each of the light-emitting elements ED above the first sub-pixel SP1, the second sub-pixel SP2, and the third sub-pixel SP3. The opening can expose one light-emitting element ED determined to be normal among a pair of light-emitting elements ED disposed in one sub-pixel.

For example, the pair of light-emitting elements ED can be disposed in each of the first sub-pixel SP1, the second sub-pixel SP2, and the third sub-pixel SP3. The pair of light-emitting elements ED can include a main light-emitting element ED and a redundancy light-emitting element ED. For example, the 1-1 light-emitting element 130a, the 2-1 light-emitting element 140a, and the 3-1 light-emitting element 150a can be the main light-emitting elements ED. In addition, the 1-2 light-emitting element 130b, the 2-2 light-emitting element 140b, and the 3-2 light-emitting element 150b can be the redundancy light-emitting elements ED.

The opening of the black matrix BM can expose one light-emitting element ED determined to be normal among the main light-emitting element and the redundancy light-emitting element disposed in one sub-pixel. Accordingly, the opening can define a light-emitting area.

Since the second optical layer 117b is disposed in the areas between neighboring sub-pixels SP1, SP2, and SP3 in the same row direction in one pixel PX, the second optical layer 117b can be disposed to vertically overlap the black matrix BM. Accordingly, it is possible to prevent color mixing between the light-emitting elements ED disposed in one sub-pixel.

A display apparatus according to various embodiments of the present disclosure can be described as follows.

A display apparatus according to an embodiment of the present disclosure can include a substrate including a plurality of pixels, a plurality of pixel driving circuits disposed on the substrate, a plurality of light-emitting elements disposed on the pixel driving circuit, a contact electrode disposed between the plurality of light-emitting elements and the pixel driving circuit and configured to electrically connected to the pixel driving circuit, a first optical layer surrounding the plurality of light-emitting elements, a second optical layer disposed outside the first optical layer, a contact hole disposed in the second optical layer, and an electrode disposed on the plurality of light-emitting elements and electrically connected to each of the plurality of light-emitting elements and to the contact electrode through the contact hole.

According to various embodiments of the present disclosure, the display apparatus can further include a third optical layer disposed on the first optical layer.

According to various embodiments of the present disclosure, the display apparatus can further include a black matrix disposed on the first optical layer, the second optical layer, and the third optical layer and including an opening corresponding to at least one of the plurality of light-emitting elements, a cover layer covering the black matrix, and a cover member disposed on the cover layer.

According to various embodiments of the present disclosure, the black matrix can be filled in the contact hole.

According to various embodiments of the present disclosure, the contact hole can have an upper portion with a greater width than a lower portion and a sidewall that connects the lower portion to the upper portion and includes an inclined surface having inclination, and an inclination angle of the sidewall of the contact hole may not exceed 90 degrees with respect to a bottom surface of the second optical layer.

According to various embodiments of the present disclosure, the first optical layer can be disposed in a line shape extending continuously in the first direction of the substrate, the second optical layer can come into contact with at least one side surface of the first optical layer and can be disposed in a line shape extending continuously in the first direction.

According to various embodiments of the present disclosure, the first optical layer can be disposed in each of the plurality of pixels, and the second optical layer can be disposed to surround four side surfaces of the first optical layer.

According to various embodiments of the present disclosure, the first optical layer can include an island shape that is distinguished with respect to each of the plurality of pixels.

According to various embodiments of the present disclosure, one of the plurality of pixels can include a plurality of sub-pixels, the first optical layer can be disposed in each of the plurality of sub-pixels, and the second optical layer can be disposed to surround four side surfaces of the first optical layer.

According to various embodiments of the present disclosure, the first optical layer can include an island shape that is distinguished with respect to each of the plurality of sub-pixels.

According to various embodiments of the present disclosure, the first optical layer can include an organic insulation material having fine particles dispersed therein, and wherein the second optical layer can include an organic insulation material.

According to various embodiments of the present disclosure, the plurality of fine particles can include titanium dioxide particles.

According to various embodiments of the present disclosure, the second optical layer can be a single component of an organic insulation material not including fine particles.

According to various embodiments of the present disclosure, the third optical layer can include an organic insulation material having fine particles dispersed therein.

According to various embodiments of the present disclosure, the plurality of light-emitting elements can be micro light-emitting elements.

According to various embodiments of the present disclosure, the plurality of light-emitting elements can include a pair of light-emitting elements that emit light of the same color, one of the pair of light-emitting elements can be a main light-emitting element, and the remaining one can be a redundant light-emitting element.

According to various embodiments of the present disclosure, the pixel driving circuit can be a micro driver.

According to various embodiments of the present disclosure, the plurality of light-emitting elements can include micro light-emitting elements having a vertical structure.

According to various embodiments of the present disclosure, the display apparatus can further include a bank on which the plurality of light-emitting elements are disposed, and a first electrode disposed between the bank and one side of each of the light-emitting elements and electrically connected to the plurality of pixel driving circuits, in which the electrode can be a second electrode disposed opposite to the first electrode and at the other side of each of the light-emitting elements.

According to various embodiments of the present disclosure, the first electrode can be disposed on an upper surface of the bank and side surfaces of the bank.

According to various embodiments of the present disclosure, the second electrode can cover an upper surface of the first optical layer and extend toward the second optical layer, and a part of the second electrode can overlap the second optical layer.

According to various embodiments of the present disclosure, the each light-emitting element can be electrically connected to the first electrode by eutectic bonding.

According to the embodiments of the present disclosure, by arranging the contact hole in which the electrode electrically connecting the pixel driving circuit to the light-emitting element in the optical layer not including fine particles, the contact hole having the size of the fine line width can be formed.

In addition, according to the embodiments of the present disclosure, by forming the contact hole in the optical layer not including fine particles, it is possible to prevent the occurrence of a pattern defect due to the residual film or a defect in which the contact hole is not formed during the process of forming the contact hole.

In addition, according to the embodiments of the present disclosure, by arranging the optical layer not including fine particles between neighboring pixels among the plurality of pixels, it is possible to prevent color mixing from occurring between neighboring pixels.

In addition, according to the embodiments of the present disclosure, by arranging the optical layer not including fine particles in the boundary area between the plurality of sub-pixels, it is possible to prevent color mixing from occurring between neighboring sub-pixels.

In addition, according to the embodiments of the present disclosure, by arranging the optical layer including a plurality of fine particles in the area corresponding to the light-emitting element, it is possible to increase the light extraction efficiency by the light scattered in the plurality of fine particles. Accordingly, the display apparatus can be driven at lower power.

Effects of the present disclosure are not limited to the above-described effects, and other effects that are not described will be able to be clearly understood by those skilled in the art based on the following description.

Although the embodiments of the present disclosure have been described in more detail with reference to the accompanying drawings, the present disclosure is not necessarily limited to these embodiments, and various modifications can be carried out without departing from the technical spirit of the present disclosure. Accordingly, the embodiments disclosed in the present disclosure are not intended to limit the technical spirit of the present disclosure, but is intended to describe the same, and the scope of the technical spirit of the present disclosure is not limited by these embodiments. Accordingly, it should be understood that the above-described embodiments are illustrative and not restrictive in all aspects.

What is claimed is:

1. A display apparatus comprising:
a substrate including a plurality of pixels;
a plurality of pixel driving circuits disposed on the substrate;
a plurality of light-emitting elements disposed on a pixel driving circuit among the plurality of pixel driving circuits;
a contact electrode disposed between the plurality of light-emitting elements and the pixel driving circuit and configured to electrically connected to the pixel driving circuit;
a first optical layer disposed adjacent to the plurality of light-emitting elements;
a second optical layer disposed outside the first optical layer,
a contact hole disposed in the second optical layer; and
an electrode disposed on the plurality of light-emitting elements, and electrically connected to each of the plurality of light-emitting elements and to the contact electrode through the contact hole.

2. The display apparatus of claim 1, further comprising a third optical layer disposed on the first optical layer.

3. The display apparatus of claim 2, further comprising:
a black matrix including an opening that is disposed above the first optical layer, the second optical layer, and the third optical layer and corresponds to at least one of the plurality of light-emitting elements;
a cover layer covering the black matrix; and
a cover member disposed on the cover layer.

4. The display apparatus of claim 3, wherein the black matrix is filled in the contact hole.

5. The display apparatus of claim 1, wherein the contact hole has an upper portion having a greater width than a lower portion, and a sidewall that connects the lower portion to the upper portion and includes an inclined surface having an inclination, and
an inclination angle of the sidewall of the contact hole does not exceed 90 degrees with respect to a bottom surface of the second optical layer.

6. The display apparatus of claim 1, wherein the first optical layer is disposed in a line shape continuously extending in a first direction of the substrate, and
the second optical layer comes into contact with at least one side surface of the first optical layer and is formed in a line shape continuously extending in the first direction.

7. The display apparatus of claim 1, wherein the first optical layer is disposed in each of the plurality of pixels, and
the second optical layer is disposed to surround four side surfaces of the first optical layer.

8. The display apparatus of claim 7, wherein the first optical layer has an island shape that is distinguished with respect to each of the plurality of pixels.

9. The display apparatus of claim 1, wherein one of the plurality of pixels includes a plurality of sub-pixels,
the first optical layer is disposed in each of the plurality of sub-pixels, and
the second optical layer is disposed to surround four side surfaces of the first optical layer.

10. The display apparatus of claim 9, wherein the first optical layer has an island shape that is distinguished with respect to each of the plurality of sub-pixels.

11. The display apparatus of claim 1, wherein the first optical layer includes an organic insulation material having fine particles dispersed therein, and
the second optical layer includes an organic insulation material.

12. The display apparatus of claim 11, wherein the fine particles include titanium dioxide particles.

13. The display apparatus of claim 12, wherein the second optical layer is a single component of the organic insulation material not including the fine particles.

14. The display apparatus of claim 2, wherein the third optical layer includes an organic insulation material having fine particles dispersed therein.

15. The display apparatus of claim 1, wherein the plurality of light-emitting elements are micro light-emitting elements.

16. The display apparatus of claim 1, wherein the plurality of light-emitting elements include a pair of light-emitting elements configured to emit light of a same color, and
one of the pair of light-emitting elements is a main light-emitting element, and the remaining one is a redundancy light-emitting element.

17. The display apparatus of claim 1, wherein the pixel driving circuit is a micro driver.

18. The display apparatus of claim 1, wherein the plurality of light-emitting elements are micro light-emitting elements having a vertical structure.

19. The display apparatus of claim 1, further comprising:
a bank on which the plurality of light-emitting elements are disposed; and
a first electrode disposed between the bank and one side of each light-emitting element, and electrically connected to the plurality of pixel driving circuits,
wherein the electrode is a second electrode disposed opposite to the first electrode and disposed at another side of each light-emitting element.

20. The display apparatus of claim 19, wherein the first electrode is disposed on an upper surface of the bank and side surfaces of the bank.

21. The display apparatus of claim 19, wherein the second electrode covers an upper surface of the first optical layer and extends toward the second optical layer, and
wherein a part of the second electrode overlaps the second optical layer.

22. The display apparatus of claim 19, wherein each light-emitting element is electrically connected to the first electrode by eutectic bonding.
